(19) United States
(12) Patent Application Publication
(10) Pub. No.: US 2009/0224294 A1
(43) Pub. Date: Sep. 10, 2009

(54) SEMICONDUCTOR DEVICE AND METHOD OF MANUFACTURING THE SAME

(75) Inventor: Hiroyuki FUJIMOTO, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/398,671

(22) Filed: Mar. 5, 2009

(30) Foreign Application Priority Data
Mar. 10, 2008 (JP) 2008-059533

(51) Int. Cl. H01L 29/78; H01L 21/8232

(52) U.S. Cl. 257/288; 438/197; 257/E21.615; 257/E29.255

(57) ABSTRACT

A method of manufacturing a semiconductor device includes the following processes. Multiple bit lines including a first silicide layer and/or a first polysilicon layer are formed. Then, multiple through holes are formed in the bit lines. Then, a first silicon layer is formed to fill the through holes. Then, a second silicon layer including a base and multiple bodies standing on the base is formed over the bit lines and the first silicon layer. Then, a gate insulating film and a gate electrode are formed to cover the bodies. Then, multiple first source-and-drain regions are formed under the respective bodies in the base. Then, multiple word lines connected to the gate electrode and including a second silicide layer and/or a second polysilicon layer are formed. Then, multiple second source-and-drain regions penetrating the word lines and connected to the respective bodies are formed.

### BACKGROUND OF THE INVENTION

1. Field of the Invention

The present invention relates to a semiconductor device including a vertical MOS transistor and a method of manufacturing the same.

Priority is claimed on Japanese Patent Application No. 2008-059533, filed Mar. 10, 2008, the content of which is incorporated herein by reference.

2. Description of the Related Art

Generally, a semiconductor device, such as vertical DRAM (Dynamic Random Access Memory) or PRAM (Phase change Random Access Memory), usually includes a substrate, bit lines made of poly-silicon provided on the substrate, silicon pillars formed by epitaxial growth in an inter-layer insulating film formed on the bit lines, and gate electrodes (word lines) made of poly-silicon provided on outer circumferences of a gate insulating film surrounding the silicon pillars (see, for example, Published Japanese Translation No. 2004-505466, and Japanese Unexamined Patent Applications, First Publication Nos. 2005-303108 and H1-087695).

However, the bit and word lines of the semiconductor device are made of poly-silicon, causing the high resistance of wirings, such as bit and word lines, and degrading the reading speed. For this reason, high-melting-point metals, such as W (tungsten), are generally used as wirings for portions requiring high thermal resistance.

A semiconductor device having a multi-layered wiring structure includes an inter-layer insulating film electrically insulating wirings in one layer from those in another layer. A silicon oxide film formed by CVD (Chemical Vapor Deposition) is used as the inter-layer insulating film.

The W is easily oxidized in an oxygen atmosphere upon the silicon oxide film being formed, and WOₓ (tungsten oxide) having a much higher resistivity than W, resulting in an increase in the resistance of wirings, adhesion loss caused by expansion of deposited layers, and the like.

To solve the problems, a method of covering an exposed W layer with a silicon nitride film as an antioxidant film, followed by forming a silicon oxide film by CVD on the silicon nitride film, is used instead of forming a silicon oxide film directly on the W wirings.

Low pressure CVD at a temperature in the range of 630 to 680° C. with dichlorosilane (SiH₂Cl₂) and ammonia (NH₃) as material gases is used to form the silicon nitride film as the antioxidant film.

Hereinafter, a conventional technology of forming capacity contact plugs between bit wirings of DRAM which are made of W is explained.

Openings are formed in an inter-layer insulating film to form contact plugs connected to diffusion regions of an MOS transistor formed under the inter-layer insulating film.

Then, an inter-layer insulating film is formed over the entire surface, followed by sequentially depositing a W film and a silicon nitride film that will be a hard mask when the W film is processed on the inter-layer insulating film by plasma CVD.

Then, the silicon nitride film is etched with a photoresist film as a mask by photolithography and dry etching. Then, the photoresist film is removed, and the W film is etched with the silicon nitride film as a mask to form bit wirings.

Then, the silicon nitride film becomes an antioxidant film by low pressure CVD at 630 to 680° C. with dichlorosilane and ammonia as material gases.

Then, an inter-layer insulating film made of a silicon oxide film is formed over the entire surface by HDP (High Density Plasma)-CVD.

At this time, the bit wirings made of the W film are covered by the antioxidant film made of the silicon nitride film, and therefore are not exposed to the oxidant atmosphere when the inter-layer insulating film is formed, thereby preventing reaction to form WOₓ and an increase in the resistance of the bit wirings.

Then, the inter-layer insulating film is planarized by CMP (Chemical Mechanical Polishing), followed by photolithography and dry etching to form capacity contact holes in the inter-layer insulating film so that the surfaces of the contact holes are exposed. Thus, capacity contact plugs are formed;

Additionally, a semiconductor-device manufacturing method in which a W nitride film is formed on the surface of a W film by thermal nitridation, such as plasma nitridation or lamp heating, is disclosed. Further, a method of forming a silicon nitride film by ALD (Atomic Layer Deposition) for alternately supplying dichlorosilane and ammonia is disclosed.

However, further improvements have been required at the process of forming the low-resistance metal wirings.

### SUMMARY

In one embodiment, there is provided a method of manufacturing a semiconductor device that may include the following processes. Multiple bit lines including a first silicide layer and/or a first polysilicon layer are formed. Then, multiple through holes are formed in the bit lines. Then, a first silicon layer is formed to fill the through holes. Then, a second silicon layer including a base and multiple bodies standing on the base is formed over the bit lines and the first silicon layer. Then, a gate insulating film and a gate electrode are formed to cover the bodies. Then, multiple first source-and-drain regions are formed under the respective bodies in the base. Then, multiple word lines connected to the gate electrode and including a second silicide layer and/or a second polysilicon layer are formed. Then, multiple second source-and-drain regions penetrating the word lines and connected to the respective bodies are formed.

In another embodiment, there is provided a semiconductor device that may include a plurality of first and second silicon pillars, bit and word lines, and first and second diffusion layers. The first silicon pillars are disposed on a surface of a semiconductor substrate. The bit line extends in a first direction and surrounds each of the first silicon pillar with an intervention of a first insulating film between a side surface of the first silicon pillar and the bit line. The second silicon pillars are disposed on each upper surface of the first silicon pillars. The word line extends in a second direction which is perpendicular to the first direction, and surrounds each of the second silicon pillars with an intervention of a second insulating film between a side surface of the second silicon pillar and the word line. The first diffusion layer is disposed at a base portion of each second silicon pillar, connects to the bit line, and functions as one of source and drain regions of a transistor. The second diffusion layer is disposed at an upper portion of each second silicon pillar, and functions as the other of the source and drain regions.

Accordingly, the resistances of the bit and word lines can be reduced.

### BRIEF DESCRIPTION OF THE DRAWINGS

The above features and advantages of the present invention will be more apparent from the following description of certain preferred embodiments taken in conjunction with the accompanying drawings, in which:

FIGS. 1 to 18 are cross-sectional views indicative of a process flow illustrating a method of manufacturing a semiconductor device according to a first embodiment of the present invention;

FIG. 19 is a cross-sectional view illustrating the semiconductor device according to the first embodiment;

FIG. 20 is a plane view illustrating the semiconductor device according to the first embodiment;

FIGS. 21 to 50 are cross-sectional views respectively illustrating modifications of the semiconductor-device manufacturing method according to the first embodiment;

FIGS. 51 to 54 are cross-sectional views respectively illustrating examples of the semiconductor device according to the first embodiment; and

FIG. 55 is a cross-sectional view illustrating regions of the semiconductor device according to the first embodiment which will be diffusion layers by impurity implantation.

### DETAILED DESCRIPTION OF THE PREFERRED EMBODIMENTS

The invention will now be described herein with reference to illustrative embodiments. The accompanying drawings explain a semiconductor device and a method of manufacturing the semiconductor device in the embodiments, and the size, the thickness, and the like of each illustrated portion might be different from those of each portion of an actual semiconductor device.

Those skilled in the art will recognize that many alternative embodiments can be accomplished using the teachings of the present invention and that the invention is not limited to the embodiments illustrated herein for explanatory purposes.

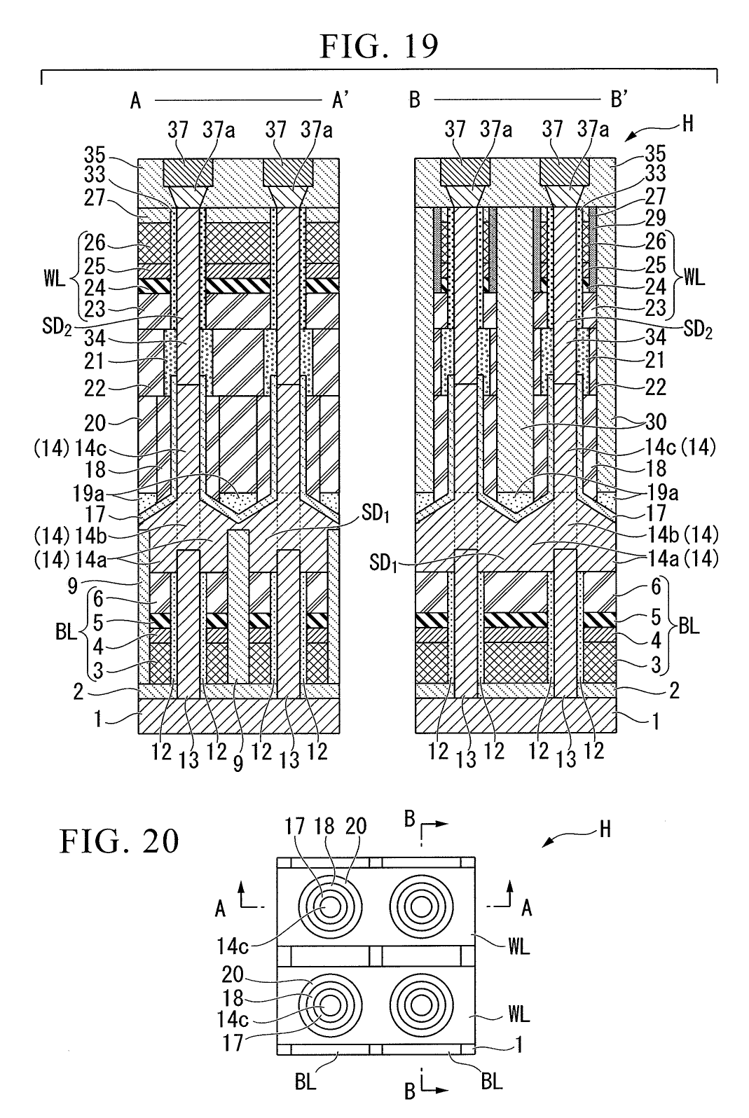

Hereinafter, a semiconductor device H according to a first embodiment of the present invention is explained. As shown in FIG. 19, the semiconductor device H mainly includes: a substrate 1; bit lines BL provided on the substrate 1 and made of first poly-metal wirings including a first silicide layer (a first W layer 3, a first WN layer 4, and a first WSi layer 5) and a first poly-silicon layer (first DOPOS (Doped Poly-Silicon layer ) 6); a second silicon layer 14 including a base portion 14a and cylindrical bodies (silicon pillars) 14c provided on the base portion 14a; source-and-drain regions SD₁ formed in the base portion 14a; a first silicon layer 13 partially penetrating the bit lines BL and connecting the substrate 1 and the second silicon layer 14; gate insulating films 17 covering the bodies 14c; gate electrodes 18 covering the bodies 14c through the gate insulating films 17; word lines made of second poly-metal wirings including a second silicide layer (a second WSi layer 24, a second WN layer 25, and a second W layer 26) and a second poly-silicon layer (fifth DOPOS layer 23), which are formed on the bodies 14c and connected to the gate electrode 18; and a third silicon layer 34 including source-and-drain regions SD₂ penetrating the word lines WL and connecting to the upper portions of the bodies 14c.

The second silicon layer 14 has a taper shape at the boundaries between the bodies 14c and the base portion 14a. Gate stoppers 19a are formed above the base portion 14a through the gate insulating film 17.

Thus, the bit lines BL and word lines WL are made of poly-metal or polycide, thereby lowering the resistances of the bit lines BL and word lines WL.

In the present invention, the bit lines BL may be poly-silicon wirings made of the first poly-silicon layer 6, and the word lines WL may be poly-metal wirings made of the second silicide layer 24 and the second poly-silicon layer 23.

Alternatively, the bit lines BL may be poly-metal wirings made of the first silicide layer 5 and the first poly-silicon layer 6, and the word lines WL may be poly-silicon made of only the second poly-silicon layer 23.

Alternatively, the bit lines BL may be poly-silicon wirings made of the first poly-silicon layer 6, and the word lines WL may be poly-silicon wirings made of only the second poly-silicon layer 23.

Hereinafter, a method of manufacturing the semiconductor device H is explained.

As shown in FIG. 1, the substrate 1 is thermally oxidized to form a first oxide film 2, followed by sequentially depositing the first W layer 3, the first WN layer 4, the first WSi layer 5, the first DOPOS layer 6, and the first nitride film 7 (step SO1). The first WSi layer 5 may be a silicide layer made of cobalt silicide (CoSi), nickel silicide (NiSi), titanium silicide (TiSi), molybdenum silicide (MoSi), chromium silicide (CrSi), or the like, as well as tungsten silicide.

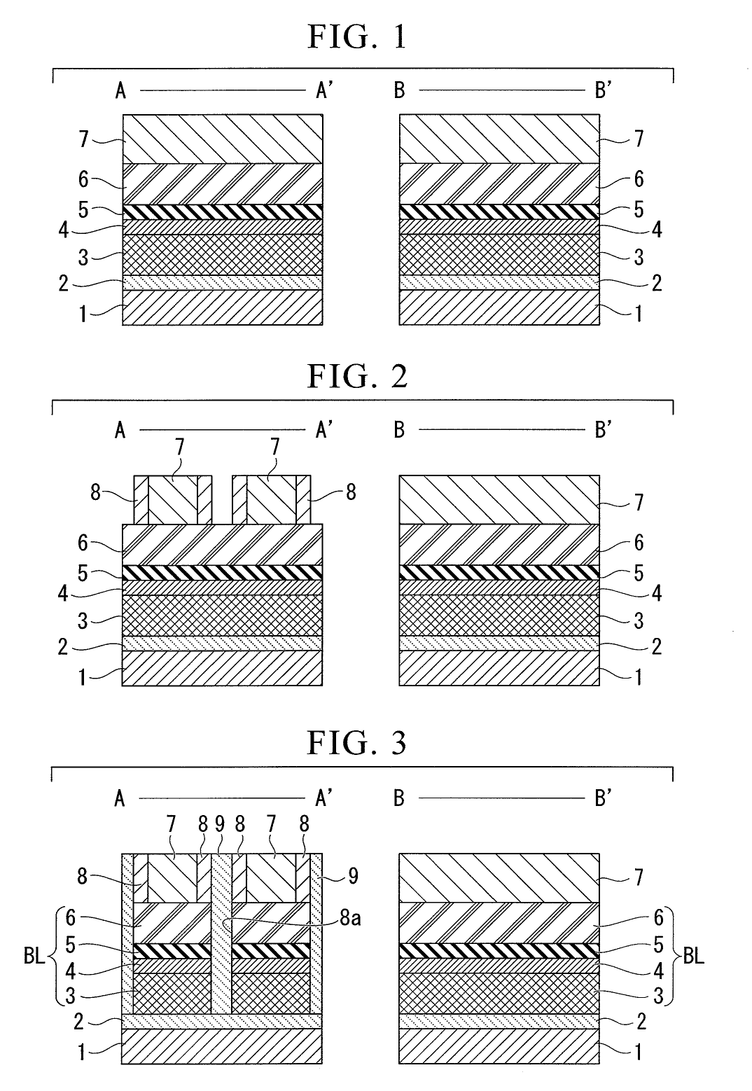

Then, the first nitride film 7 is dry-etched to be in a line-and-space pattern by lithography, as shown in FIG. 2. Then, the resist film is removed to form a first sidewall oxide film 8 (step S02).

Then, the first DOPOS layer 6, the first WSi layer 5, the first WN layer 4, and the first W layer 3 are dry-etched by lithography with the first nitride film 7 and the first sidewall oxide film 8 as masks to form a recess 8a, as shown in FIG. 3 (step S03). Even if through holes 7b are misaligned when the through holes 7b shown in FIG. 5 are formed in the following process, there is a margin corresponding to a thickness of the sidewall oxide film 8, thereby increasing allowable degree of misalignment.

Then, a second oxide film 9 is formed to fill the recess 8a, followed by CMP to planarize the first nitride film 7, the first sidewall oxide film 8, and the second oxide film 9.

In this manner, the bit lines BL including the first W layer 3, the first WN layer 4, and the first DOPOS layer 6 are divided by the second oxide film 9. Other refractory metal material can be used for bit lines such as the first W layer 3 and the first WN layer 4. In another case, only the first DOPOS layer 6 may be deposited to form the bit lines BL. In this case, the first W layer 3 and the first WN layer 4 are not formed, thereby decreasing the number of processes.

By the bit lines BL being made of only the first DOPOS layer 6, the thermal resistances of the bit lines BL increase, enabling annealing for recovering crystal defects at a higher temperature in the following process.

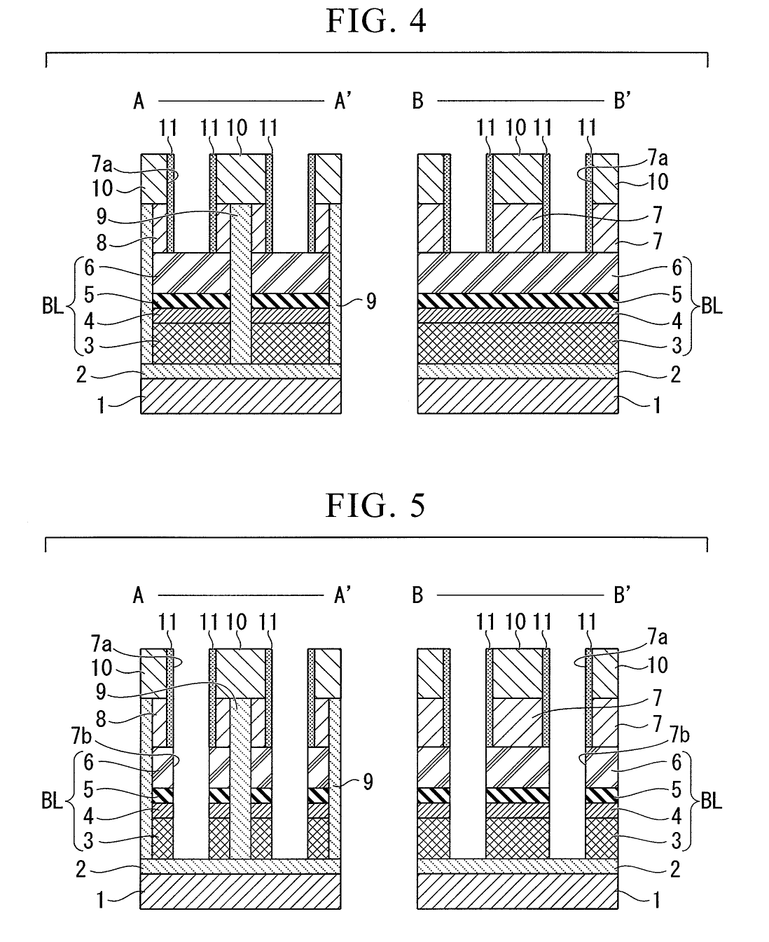

Then, a second nitride film 10 is formed to cover the first nitride film 7, the first sidewall oxide film 8, and the second oxide film 9 which have been planarized, followed by lithography to form multiple openings 7a penetrating the first nitride film 7 and the second nitride film 10 along the longitudinal direction of the first nitride film 7, as shown in FIG. 4. An inner diameter of the opening 7a is, for example, substantially the same as a width of the first nitride film 7. Then, first sidewall nitride films 11 are formed on sidewalls of the openings 7a by forming nitride films on the entire inner surfaces of the openings 7a and then etching back only the bottom surfaces thereof (step S04).

Then, through holes 7b penetrating the first DOPOS layer 6, the first WSi layer 5, the first WN layer 4, and the first W layer 3 are formed by dry etching with the second nitride film 10 and the first sidewall nitride film 11 as masks, as shown in FIG. 5 (step S05). Thereby, the through holes 7b and the openings 7a are connected.

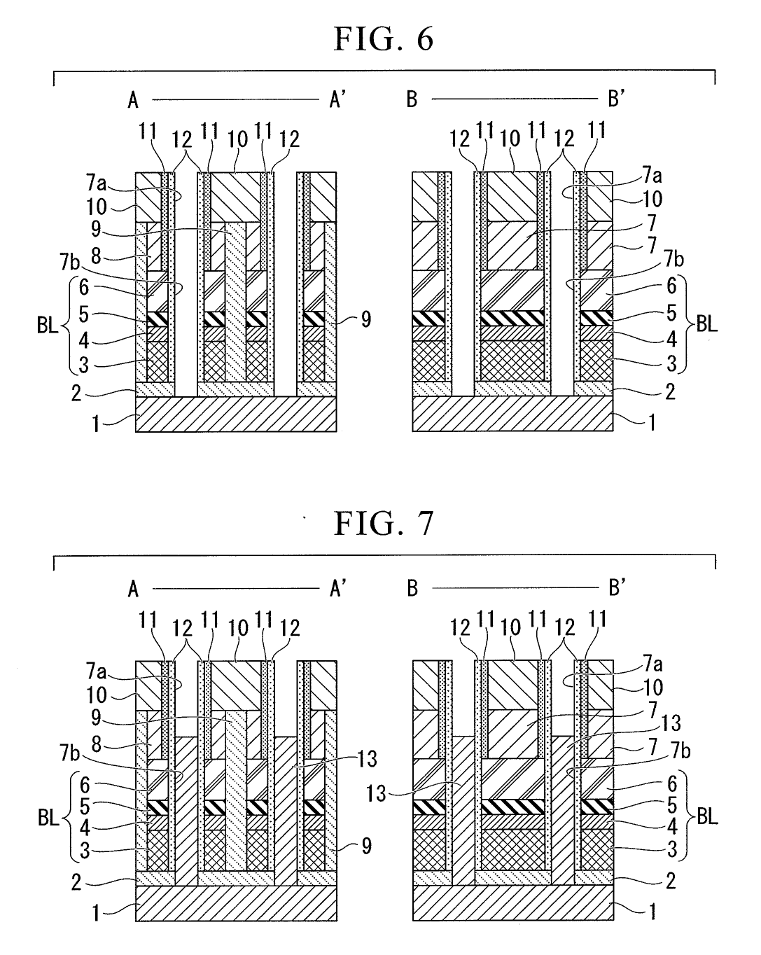

Then, third oxide films 12 that will be insulating films for the bit lines BL are formed on sidewalls of the through holes 7b and the openings 7a by forming silicon oxide films on the entire inner surfaces of the through holes 7b and the openings 7a and then dry etching only the bottom surfaces of the through holes 7b, as shown in FIG. 6 (step S06). At this time, the first oxide film 2 is removed, and the substrate 1 is exposed.

Then, a first silicon layer (first silicon pillar) 13 is formed inside the through holes 7b and the openings 7a by selective epitaxial growth, as shown in FIG. 7 (step S07). Then, hydrogen annealing may be carried out on the first silicon layer 13. At this time, the first silicon layer 13 is formed such that the upper surface of the first silicon layer 13 is higher than that of the first DOPOS layer 6 forming the bit lines BL. Thereby, the first silicon layer 13 can protrude from the first DOPOS layer 6 in the following process.

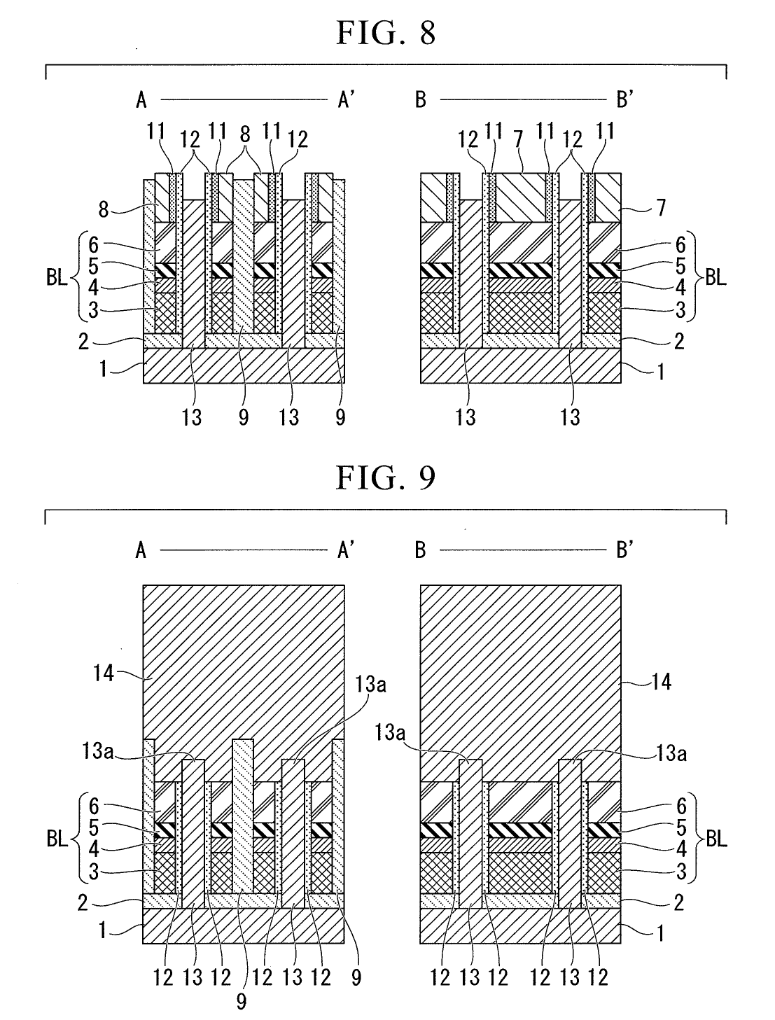

Then, the second nitride film 10 and the first sidewall nitride film 11 are partially removed by wet etching, as shown in FIG. 8. Further, the upper portions of the third oxide film 12 and the second oxide film 9 are removed by wet etching (step S08). The third oxide film 12 is etched until the height of the third oxide film 12 becomes the same as that of the first sidewall nitride film 11. The second oxide film 9 is etched until the upper surface of the second oxide film 9 becomes lower than that of the first nitride film 7.

Then, the first nitride film 7, the first sidewall nitride film 11, and the first sidewall oxide film 8 are removed by wet etching, as shown in FIG. 9. Further, the upper portions of the second and third oxide films 9 and 12 are removed by dry etching. The third oxide film 12 is etched until the height of the third oxide film 12 becomes the same as that of the first DOPOS layer 6. Thereby, the first silicon layer 13 protrudes from the first DOPOS layer 6. The protruding portions are regarded as protruding portions 13a.

Then, the second silicon layer 14 is deposited over the entire surface by selective epitaxial growth (step S09). Thereby, the second silicon layer 14 is connected to the substrate 1 through the first silicon layer 13.

The second silicon layer 14 is formed by epitaxial growth with the protruding portions 13a of the first silicon layer 13 as seeds. Since the first silicon layer 13 has epitaxially grown from the substrate 1, the second silicon layer 14 has a crystal structure reflecting the crystal structures of the substrate 1 and the first silicon layer 13. Laser annealing or hydrogen annealing may be carried out upon the epitaxial growth. As a result, crystal defects included in the second silicon layer 14 forming the bodies 14c can be reduced, thereby reducing a leak current and enhancing the characteristics of the device.

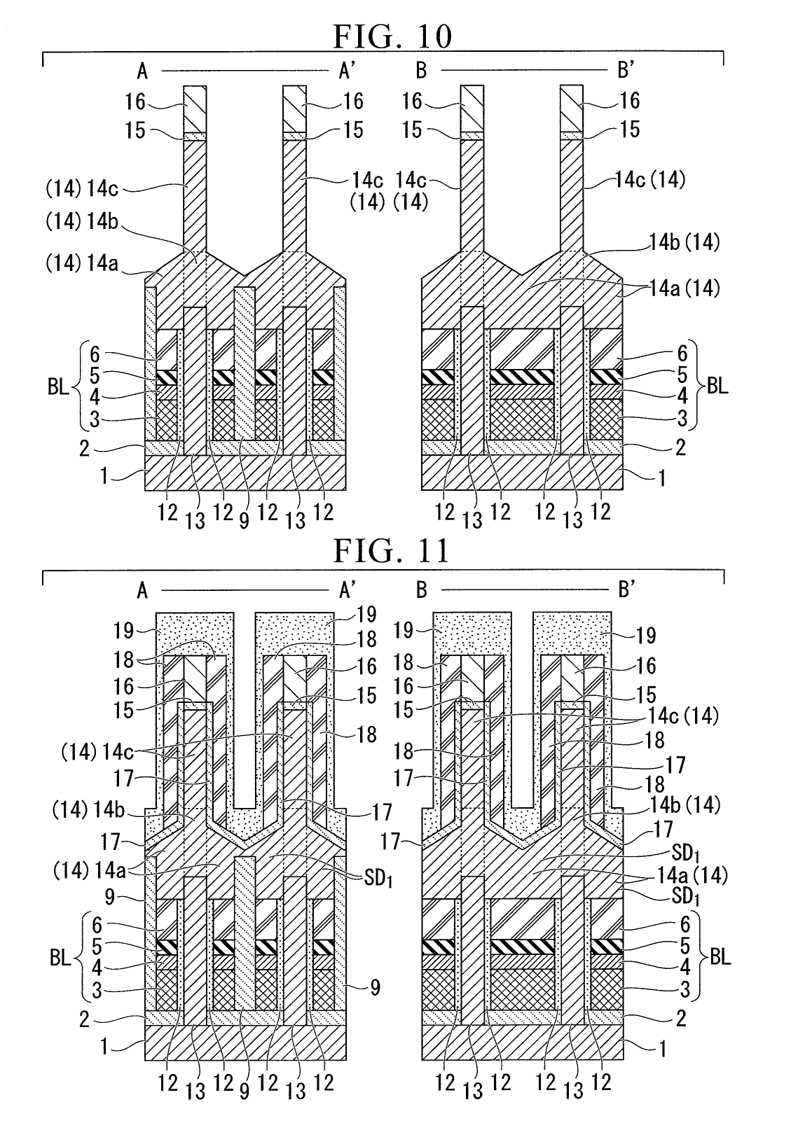

Then, a fourth oxide film 15 is formed on the second silicon layer 14 by thermal oxidation, as shown in FIG. 10. Then, a third nitride film 16 is formed on the fourth oxide film 15. Then, the third nitride film 16 is patterned to be circular by lithography, followed by dry etching the third nitride film 16. At this time, the third nitride film 16 may be isotropically etched so as to be thinner. Then, the fourth oxide film 15 and the second silicon layer 14 are dry etched so as to be circular. At this time, the etching is carried out so that lower portions of the second silicon layer 14 are tapered. Thus, the second silicon layer (second silicon pillar) 14 is shaped to be the base portion 14a formed on the first DOPOS layer 6 and the bodies 14c standing on the base portion 14a (step S10).

Additionally, an impurity is implanted into the base station 14a to form diffusion layers, thereby forming the source-and-drain regions SD₁. At this time, different diffusion layers may be formed in the base pillars 14b above the first silicon layer 13 in the base portions 14a. Additionally, an impurity is implanted into the bodies 14c to form diffusion layers, thereby forming channel regions.

Then, the entire surfaces of the base portion 14a and the bodies 14c are thermally oxidized to form the gate insulating film 17 made of silicon oxide, as shown in FIG. 11. Then, a second DOPOS layer 18 with a substantially even thickness is formed to fill the bodies 14c. Then, the second DOPOS layer 18 is etched so as to cover sidewalls of the bodies 14c and expose the gate insulating film 17 on the base portion 14a. Then, an N-type impurity is diffused into the base portion 14a through the gate insulating film 17 by ion implantation to form the source-and-drain regions SD₁. Then, an HDP layer 19 is formed by high-density plasma CVD to cover the second DOPOS layer 18 and the exposed gate insulating film 17 (step S11).

At this time, conditions of the high-density plasma CVD are controlled so that the HDP layer 19 formed on the sidewalls of the bodies 14c are thinner, and the HDP layer 19 covering the gate insulating film 17 on the base portion 14a is thicker.

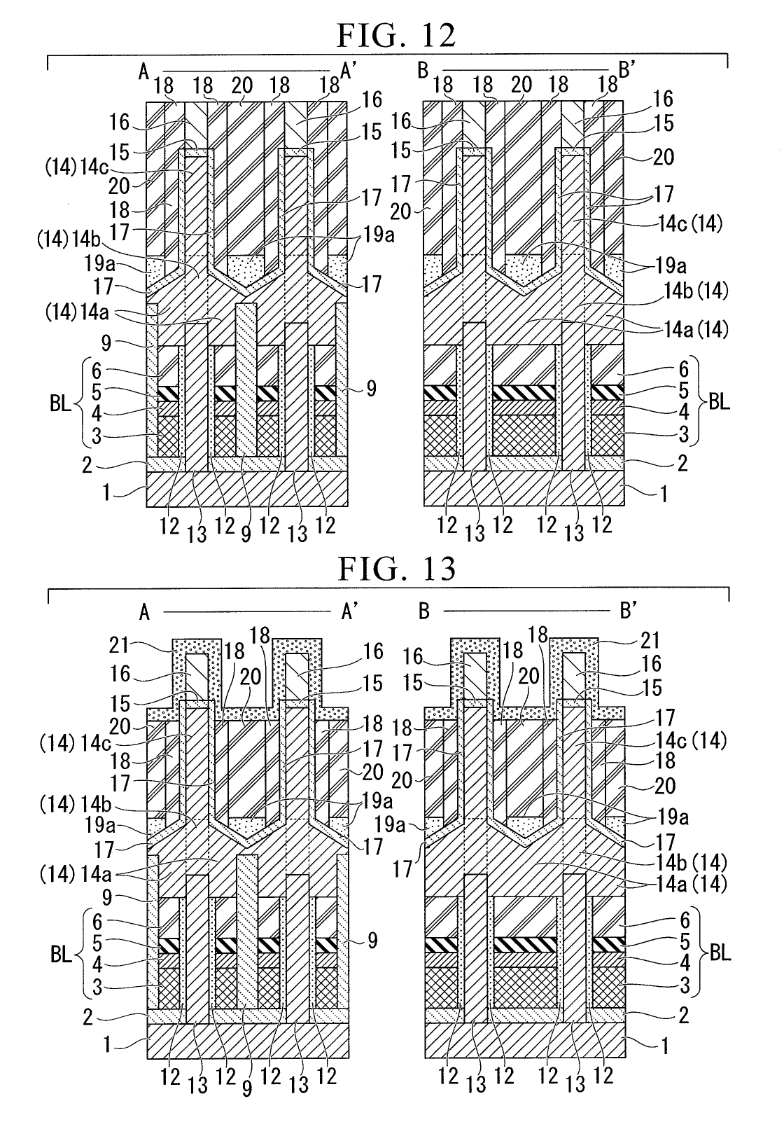

Then, the HDP layer 19 is removed by wet etching (isotropic etching) with portions on the base portion 14a remained, as shown in FIG. 12. At this time, the HDP layer 19 remaining on the base portion 14a forms the gate stoppers 19a. Since the gate stoppers 19a function as stoppers for cutting gate wirings, gate overlapping capacity can be reduced.

Then, a third DOPOS layer 20 is formed to cover the second silicon layer 14 and the HDP layer 19. Then, the second and third DOPOS layer 18 and 20 are planarized by CMP so as to be equal in height to the third nitride film 16 (step S12).

Then, the second and third DOPOS layers 18 and 20 are dry-etched so as to be slightly lower than the second silicon layer 14 (bodies 14c), followed by forming a fifth oxide film 21 over the entire surface, as shown in FIG. 13 (step S13).

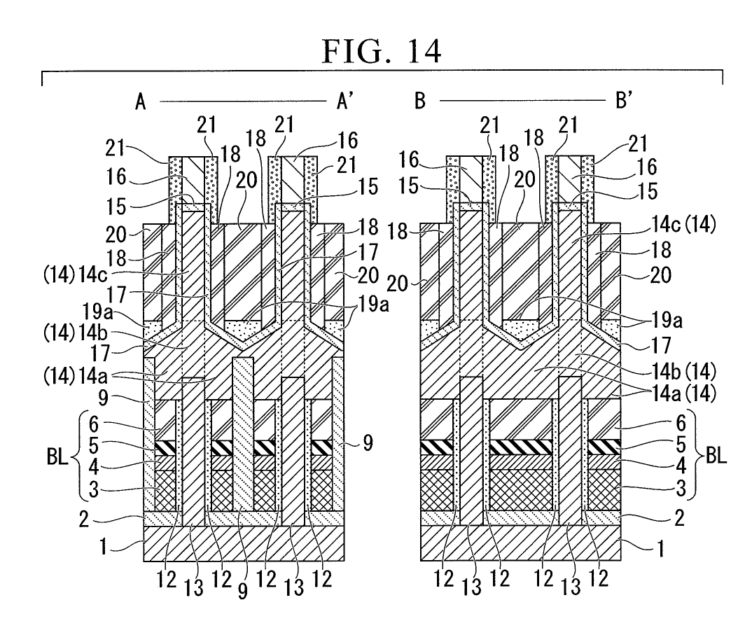

Then, the fifth oxide film 21 are removed by dry etching with the portions in contact with the sidewalls of the third nitride film 16 being left, as shown in FIG. 14 (step S14). Thus, the fifth oxide film 21 surrounds the third nitride film 16, enabling the third nitride film 16 to be substantially thicker.

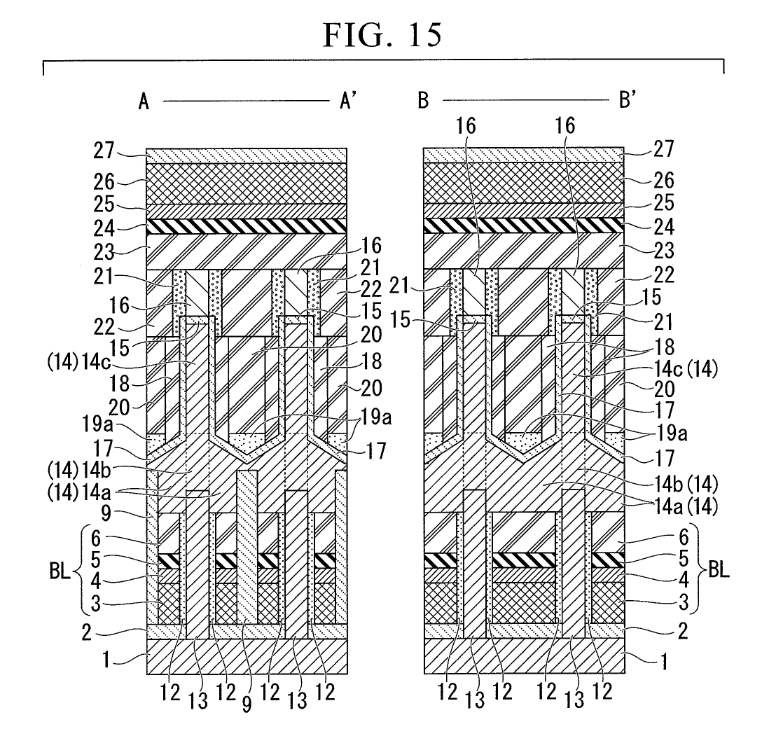

Then, a fourth DOPOS layer 22 is formed to cover the second and third DOPOS layers 18 and 20, followed by CMP to make the fourth DOPOS layer 22 equal in height to the third nitride film 16, as shown in FIG. 15. Then, the fifth DOPOS layer 23, the second WSi layer 24, the second WN layer 25, the second W layer 26, and the sixth oxide film 27 are sequentially deposited to cover the fourth DOPOS layer 22 and the third nitride film 16 (step S15). The second WSi layer 24 may be a silicide layer made of cobalt silicide (CoSi), nickel silicide (NiSi), titanium silicide (TiSi), molybdenum silicide (MoSi), chromium silicide (CrSi), or the like, as well as tungsten silicide.

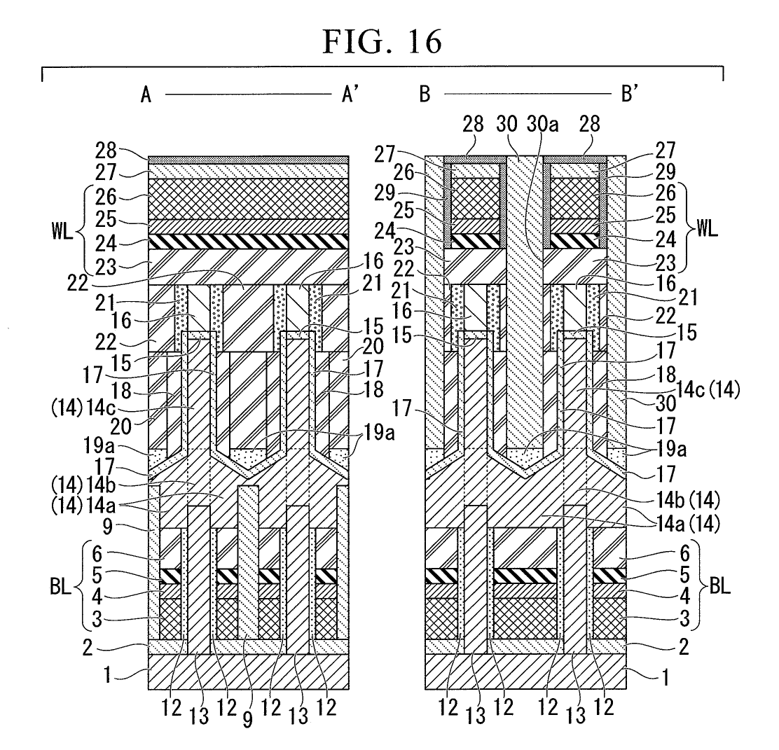

Then, the sixth oxide film 27 is dry-etched and patterned by lithography, followed by the fifth DOPOS layer 23, the second WSi layer 24, the second WN layer 25, the second W layer 26, and the sixth oxide film 27 are patterned in a line-and-space pattern with the sixth oxide film 27 as a mask, as shown in FIG. 16. At this time, the fifth DOPOS layer 23 and the like are patterned so as to extend in the direction perpendicular to the longitudinal direction of the first nitride film 7. Then, second sidewall oxide films 29 are formed to cover the fifth DOPOS layer 23, the second WSi layer 24, the second WN layer 25, the second W layer 26, and the sixth oxide film 27. Then, the third and fourth DOPOS layers 20 and 22 are dry-etched to form a recess 30a. Then, an eighth oxide film 30 is formed to fill the recess 30a.

Thus, the word lines WL including the fifth DOPOS layer 23, the second WSi layer 24, the second WN layer 25, and the second W layer 26 (step S16). Other refractory metal material can be used for word lines such as the second WSi layer 24, the second WN layer 25, and the second W layer 26. In another case, only the fifth DOPOS layer 23 may be deposited to form the word lines WL shown in FIG. 15, enabling the word lines WL to be formed at a narrower pitch, and therefore enhancing the integration of the semiconductor device.

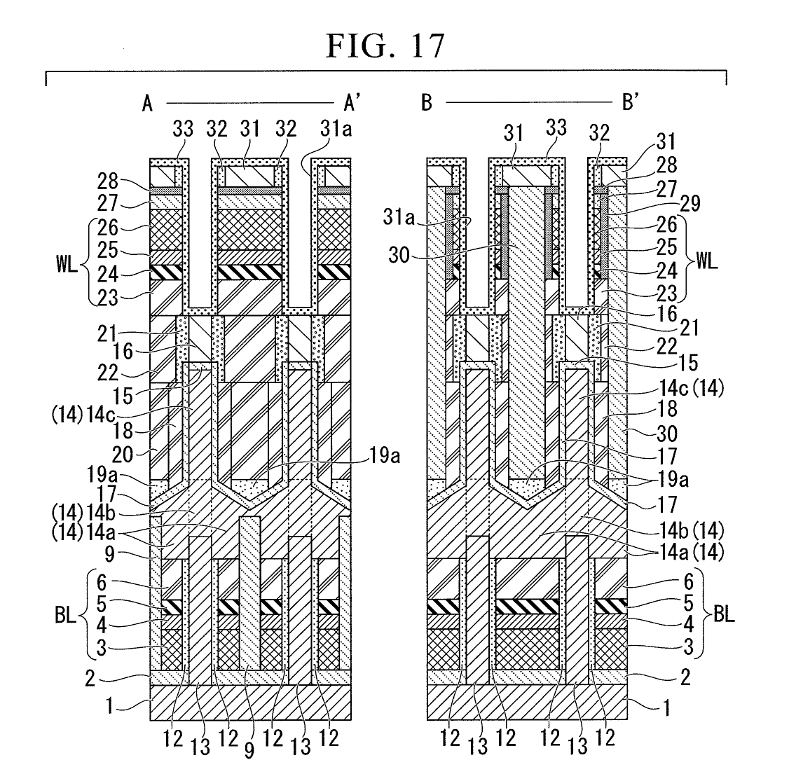

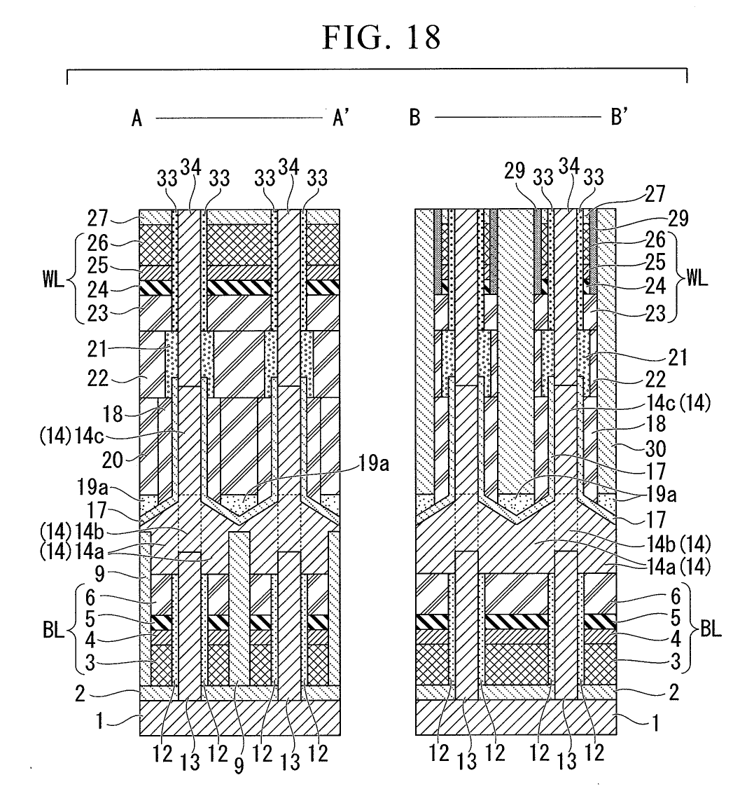

Then, the seventh and eighth oxide film 28 and 30 are planarized by CMP, followed by forming a fourth nitride film 31 on the seventh and eighth oxide films 28 and 30, as shown in FIG. 17. Then, the nitride film 31 is patterned by dry etching to have openings, followed by removing the resist film. Then, a nitride film is formed and etched back to form the second sidewall nitride film 32. Then, the seventh oxide film 28, the sixth oxide film 27, the second W layer 26, the second WN layer 25, the second WSi layer 24, and the fifth DOPOS layer 23 are dry-etched with the fourth nitride film 31 and the second sidewall nitride film 32 as masks to form openings 31a. Then, a ninth oxide film 33 is formed to cover the inner surfaces of the openings 31a, the fourth nitride film 31, and the second sidewall nitride film 32 (step S17).

Then, the ninth oxide film 33 is dry-etched to remove the ninth oxide film 33 on the bottom surfaces of the openings 31a and leave the ninth oxide film 33 on the sidewalls of the openings 31a, as shown in FIG. 18. Then, the fourth nitride film 31, the second sidewall nitride film 32, and the third nitride film 16 are removed by dry etching. At this time, the fifth oxide film 21 has been formed to cover the third nitride film 16. Therefore, even if the openings 31 a are slightly misaligned in the previous process, only the third nitride film 16 is etched by self alignment so that the openings 31a can be deeply formed. Thus, a margin for alignment of the openings 31a in the previous process can be largely obtained because of the fifth oxide film 21.

Then, the fourth oxide film 15 is removed by dry etching, followed by epitaxial growth to form the third silicon layer 34. Thus, the third silicon layer 34 and the bodies 14c are connected (step S18). As explained layer, an impurity is implanted into the third silicon layer 34 to form diffusion layers, thereby forming the source-and-drain regions SD₂.

Finally, an inter-layer insulating film 35 is formed to cover the third silicon layer 34, and capacitors 37 and capacitor contact plugs 37a connecting the capacitors 37 and the third silicon layer 34 are formed in the inter-layer insulating film 35, as shown in FIG. 19 (step S19).

Then, if a wiring layer is formed by a known method, the semiconductor device can be used as a ZRAM (zero capacitor RAM) that is a memory storing holes in a body region of a transistor. A phase-change material may be deposited instead of the capacitor 37 shown in FIG. 19 (step S19). If the capacitor 37 is deposited, the semiconductor device can be used as a DRAM. If the phase-change material is deposited, the semiconductor device can be used as a PRAM.

To use the above structure as a device, impurities are implanted into the substrate 1 and the first to third silicon layers 13, 14, and 34 to form diffusion layers. Diffusion layers for a P-type or N-type semiconductor device can be formed according to the type of impurity to be implanted. For example, the following combinations can be considered.

The first case is an N-channel transistor H1 shown in FIG. 51 in which the first silicon layer 13 made of a P-type semiconductor connects the body 14c and the substrate 1.

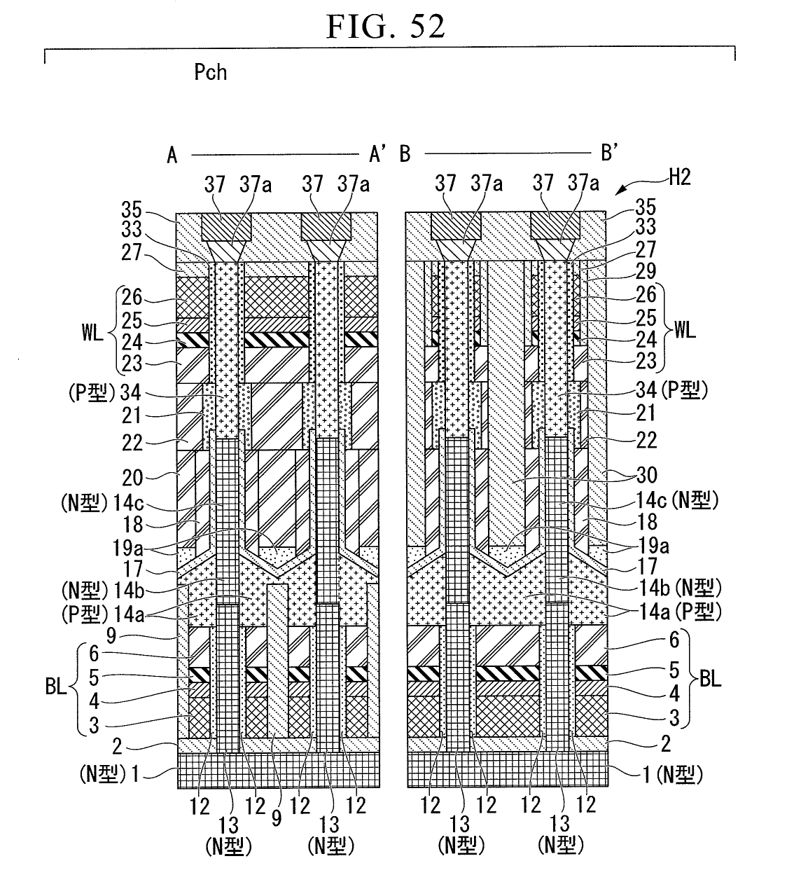

The second case is a P-channel transistor H2 shown in FIG. 52 in which the first silicon layer 13 made of an N-type semiconductor connects the body 14c and the substrate 1.

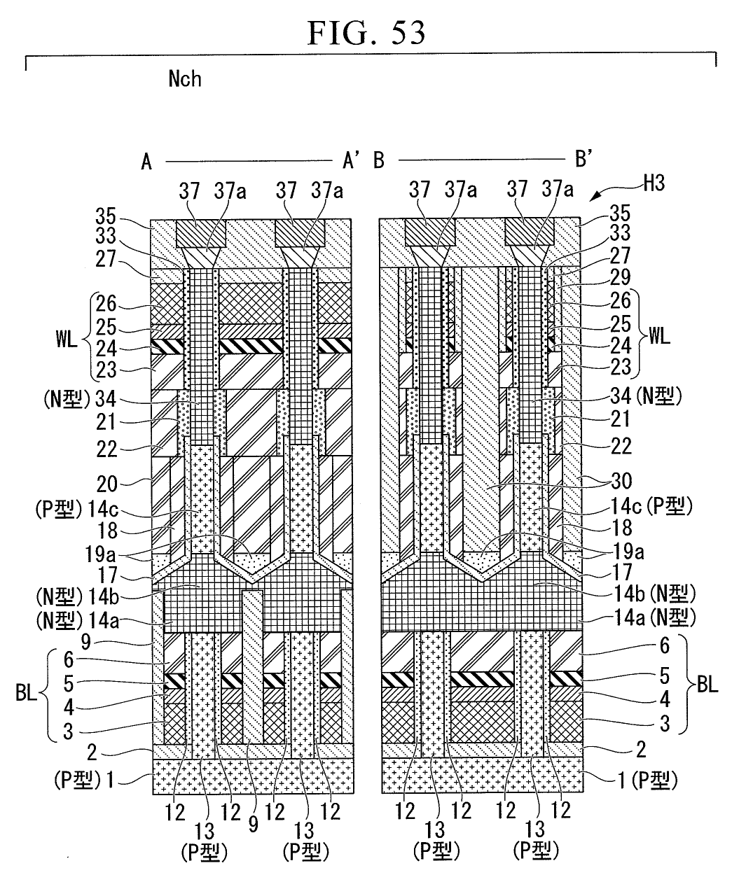

The third case is an N-channel transistor H3 shown in FIG. 53 in which the body 14c and the substrate 1 are both P-type and isolated from each other by a base pillar 14b made of an N-type semiconductor.

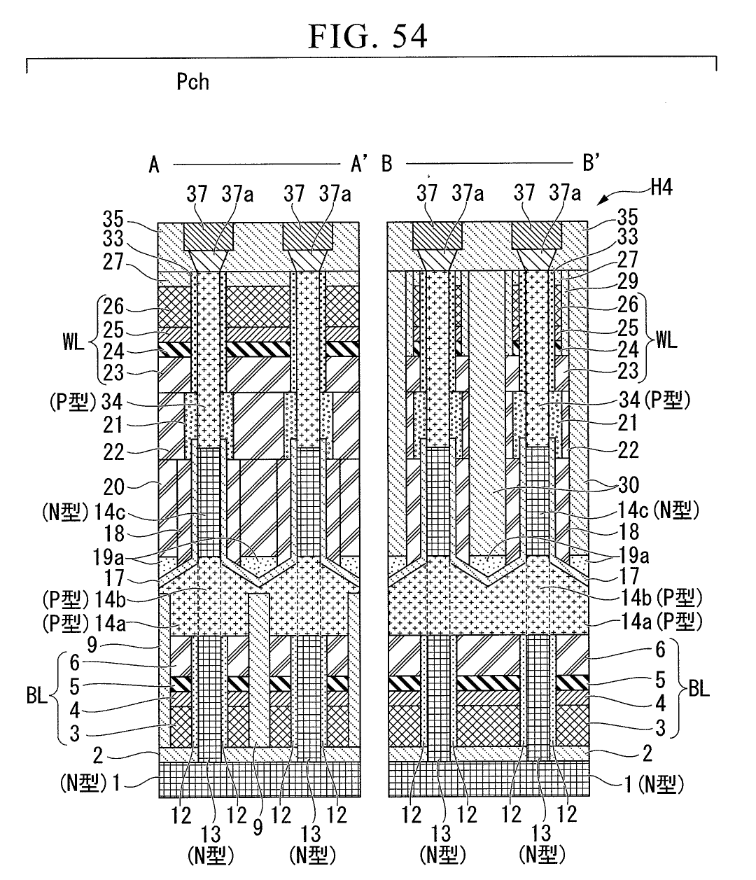

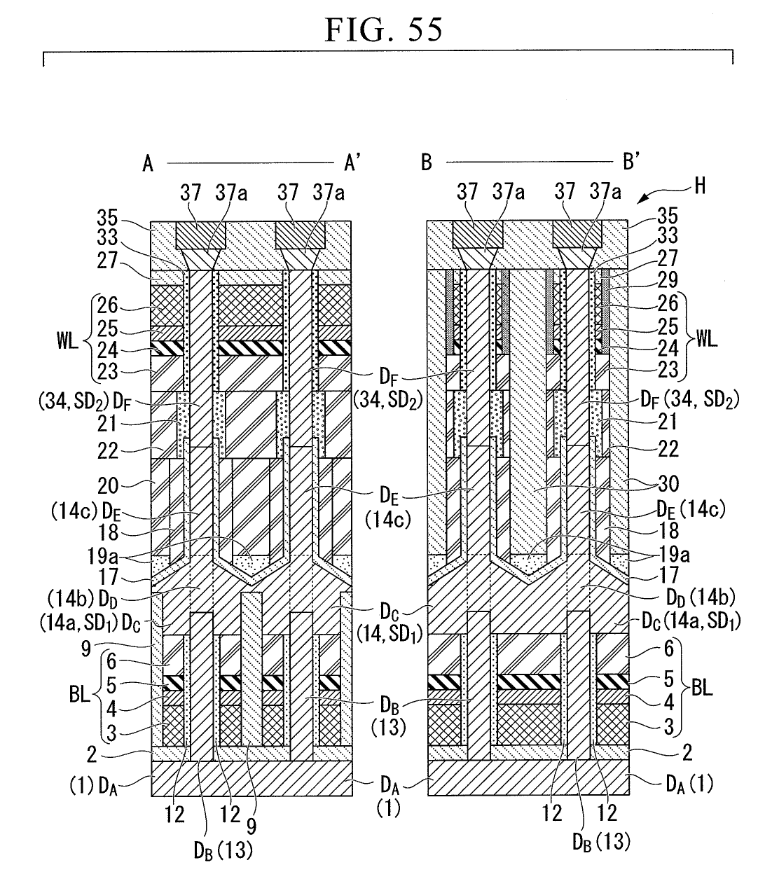

The fourth case is a P-channel transistor H4 shown in FIG. 54 in which the body 14c and the substrate 1 are both N-type and isolated from each other by the base pillar 14b made of a P-type semiconductor.

There are three methods of impurity implantation. The first one is ion implantation. The second one is to diffuse an impurity simultaneously with epitaxial growth. The third one is solid-phase diffusion by annealing after an epitaxial layer is formed while an impurity in a DOPOS layer is highly concentrated.

Hereinafter, regions D_{A} to D_{F} that will be an N-type or P-type semiconductor device are explained with reference to FIG. 55.

An impurity is preferably ion-implanted into the region DA (substrate 1) before the thermal oxidation shown in FIG. 1.

The region D_{B} (first silicon layer 13) can be formed by: diffusing an impurity simultaneously with the selective epitaxial growth shown in FIG. 7 (step S07); highly concentrating an impurity included in the DOPOS layer upon the DOPOS growth shown in FIG. 4 (step S04) and then performing annealing for solid-phase diffusion after the epitaxial layer is formed as shown in FIG. 9 (step S09); or ion-implanting an impurity after the epitaxial growth shown in FIG. 8 (step S08).

The annealing may be laser annealing or hydrogen annealing. Thus, crystal defects that have occurred upon the epitaxial growth can be recovered by a combination of epitaxial growth and annealing, thereby enhancing the characteristics of a device to be achieved.

The region D_{C} (substrate 14a) can be formed by: diffusing an impurity simultaneously with the selective epitaxial growth shown in FIG. 9 (step S09); highly concentrating an impurity included in the DOPOS layer upon the DOPOS growth shown in FIG. 4 (step S04), and performing annealing for solid-phase diffusion after the epitaxial layer is formed as shown in FIG. 9 (step S09); ion-implanting an impurity after the epitaxial growth shown in FIG. 9 (step S09); ion-implanting an impurity after the gate oxidation shown in FIG. 11 (step S11); or ion-implanting an impurity after the HDP layer is formed as shown in FIG. 11 (step S11). In this manner, the source-and-drain region SD₁ is formed in the region D_{C}.

The region D_{D} (base pillar 14b) can be formed by: diffusing an impurity simultaneously with the selective epitaxial growth shown in FIG. 9 (step S09); highly concentrating an impurity included in a DOPOS layer upon the DOPOS growth shown in FIG. 4 (step S04), and performing annealing for solid-phase diffusion after the epitaxial layer is formed as shown in FIG. 9 (step S09); ion-implanting an impurity after the epitaxial growth shown in FIG. 9 (step S09); or ion-implanting an impurity after the nitride film is dry etched as shown in FIG. 18 (step S18).

The region D_{E} (body 14a) can be formed by: diffusing an impurity simultaneously with the selective epitaxial growth shown in FIG. 9 (step S09); ion-implanting an impurity after the epitaxial growth shown in FIG. 9 (step S09); or ion-implanting an impurity after the nitride film is dry etched as shown in FIG. 18 (step S18).

The region D_{F} (second silicon layer 34) can be formed by: diffusing an impurity simultaneously with the selective epitaxial growth shown in FIG. 18 (step S18); ion-implanting an impurity after the epitaxial growth shown in FIG. 18 (step S18); or ion-implanting an impurity after the contacts are formed as shown in FIG. 19 (step S19). In this manner, the source-and-drain region SD₂ is formed in the region D_{F}.

The present invention is not limited to the first embodiment, and the following modifications may be made.

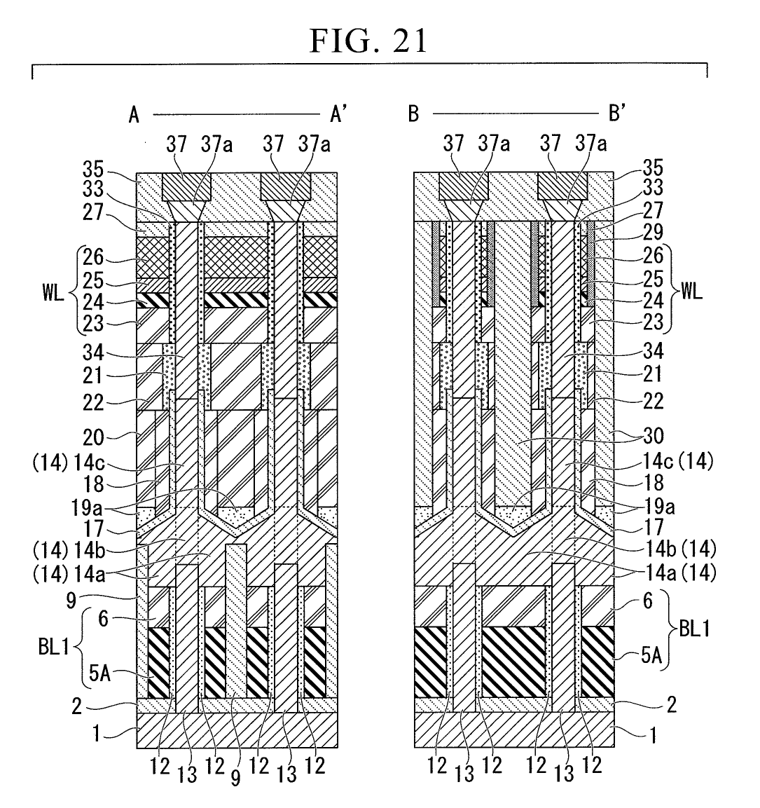

For example, the bit lines BL1 may be made of polycide as shown in FIG. 21. In this case, the bit lines BL1 are formed by the WSi layer 5A and the first DOPOS layer 6, and processing of the WN and W layers may be omitted. Thereby, the number of processes can be reduced.

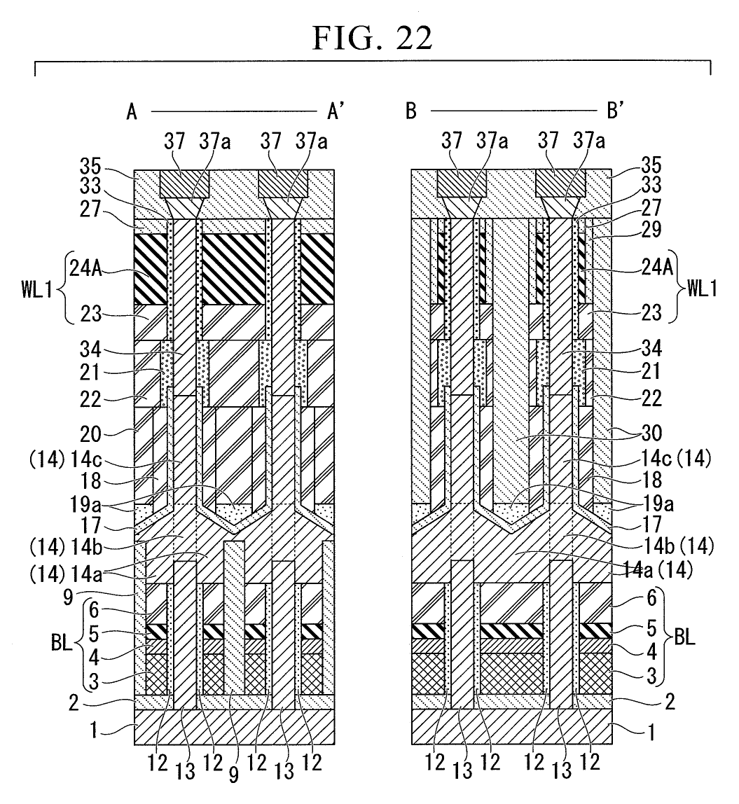

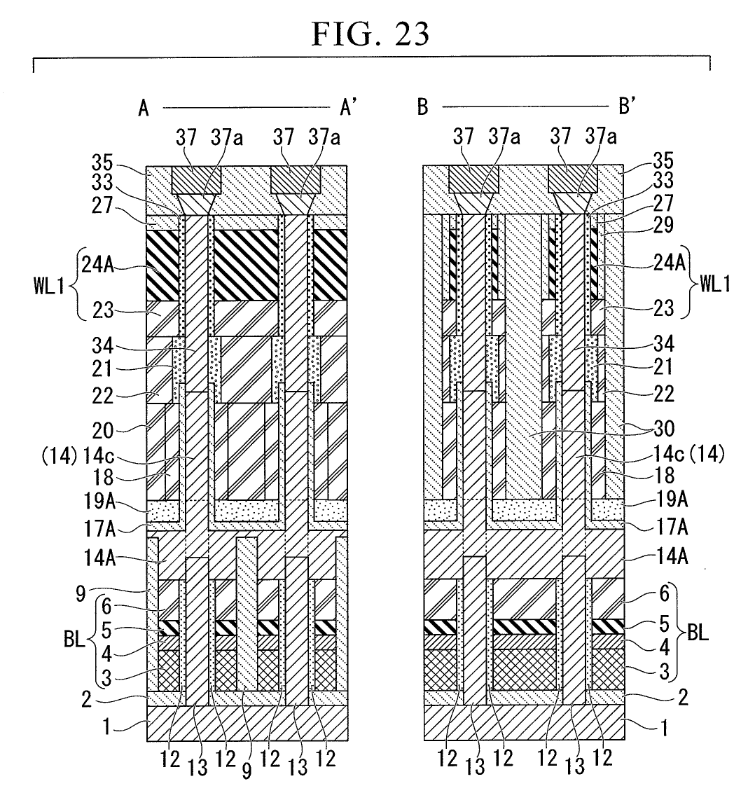

Additionally, the word lines WL1 may be made of polycide as shown in FIG. 22. In this case, the word lines WL1 are formed by the WSi layer 24A and the fifth DOPOS layer 23, and formation of the WN and W layers may be omitted. Thereby, the number of processes can be reduced.

Further, the upper portions of the second silicon layer 14A may not be tapered upon being dry etched, followed by forming the gate insulating film 17A and the HDP layer 19A. Then, the same processes follow. Thereby, silicon etching can be simplified.

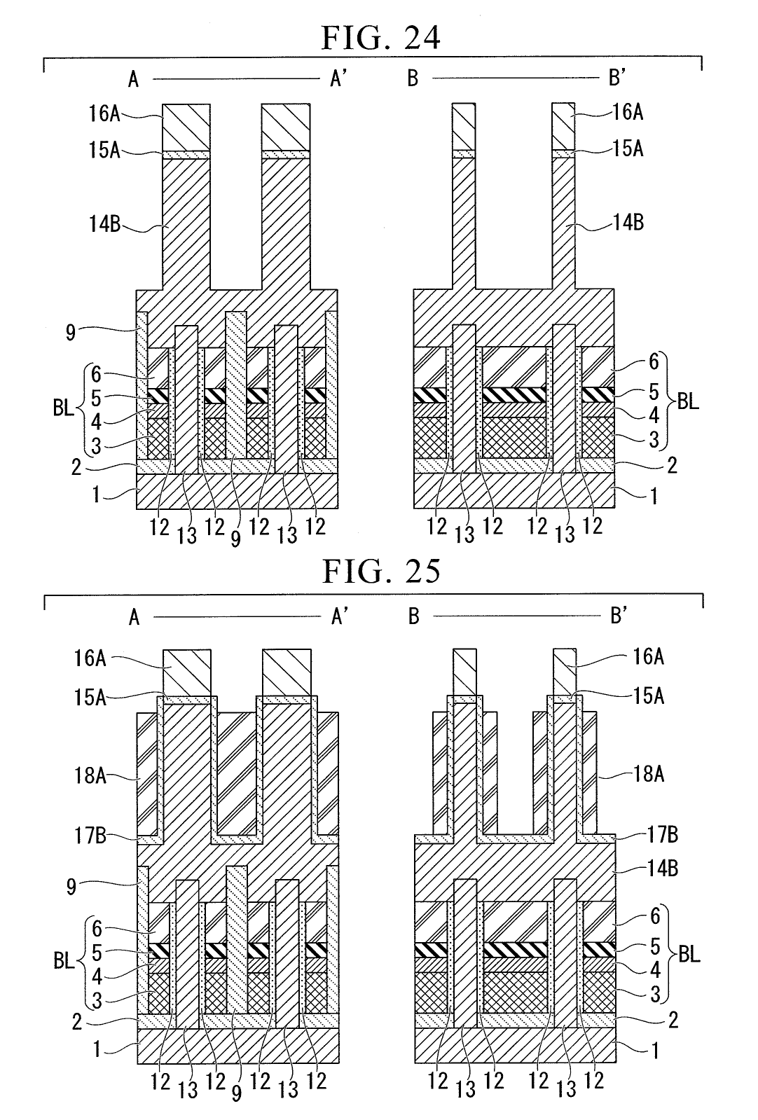

Moreover, word lines may be formed by self alignment as shown in FIGS. 24 to 26. After the structure shown in FIG. 9 (step S09) is formed, patterning into an elliptical shape longer in the direction of the word lines, dry etching of a nitride film, removal of a resist film, and dry etching of an oxide film and silicon are carried out by thermal oxidation, growth of a nitride film, and lithography. As a result, the body of the second silicon layer 14B, the fourth oxide film 15A, and the third nitride film 16A have elliptical cross sections, and thereby the structure shown in FIG. 24 is formed.

Then, a gate insulating film 17B is formed, followed by formation of a DOPOS layer and then etch back of the DOPOS layer to form a second DOPOS layer 18A. Thereby, the structure shown in FIG. 25 is formed.

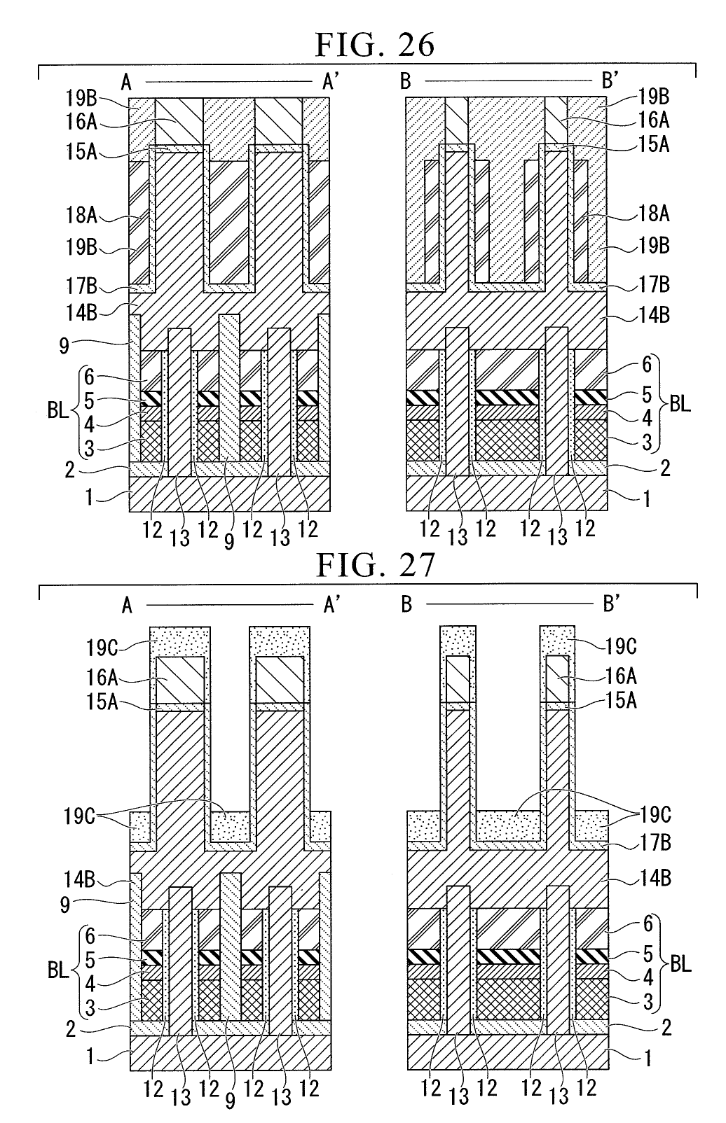

Then, an oxide film 19B is formed by growth of an oxide film and CMP, thereby forming the structure shown in FIG. 26.

Then, the device can be made by similar processes following the process shown in FIG. 15 (step S15). Thus, the number of processes can be reduced.

Alternatively, word lines may be formed by self alignment with an oxide film (HDP layer) being formed under a transistor, as shown in FIGS. 27 to 29.

Thermal oxidation is carried out after the structure shown in FIG. 24 is formed, followed by growth of an HDP layer to form an HDP layer 19C. Thus, the structure shown in FIG. 27 is formed.

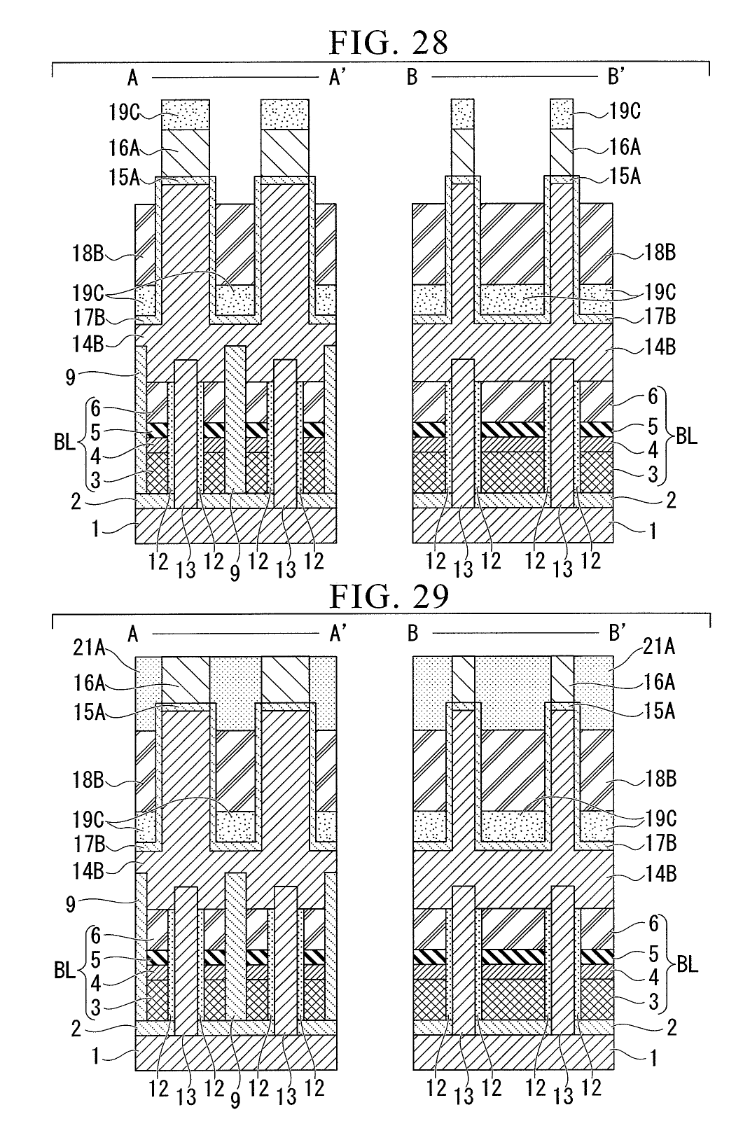

Then, the oxide film is wet etched, followed by gate oxidation to form the gate insulating film 17B. Then, growth and dry etching of the DOPOS layer are sequentially carried out to form a second DOPOS layer 18B, thus forming the structure shown in FIG. 28.

Then, growth and CMP of an oxide film is sequentially carried out to form a fifth oxide film 21A, thus forming the structure shown in FIG. 29.

Then, the device can be made by similar processes following the process shown in FIG. 15 (step S15). By the HDP layer 19C being formed in this manner, gate overlapping capacity can be reduced.

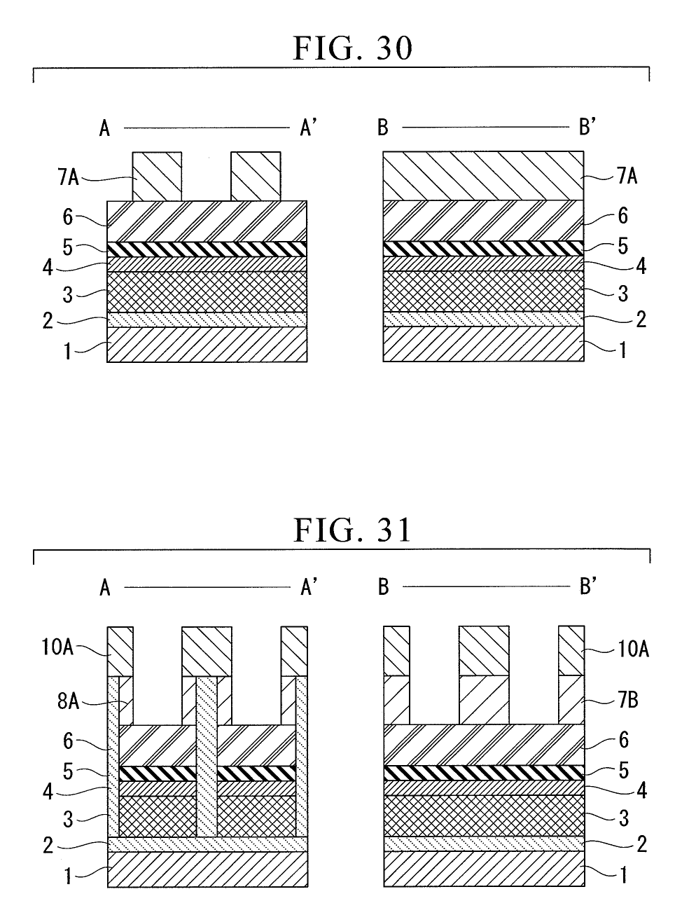

Additionally, after the process shown in FIG. 1 (step S01), patterning in a line-and-space pattern by lithography, dry etching of a nitride film, removal of a resist film are carried out to form a first nitride film 7A as shown in FIG. 30, followed by the process shown in FIG. 3 (step S03). Thereby, the number of processes can be reduced (formation of the first sidewall film 8 can be omitted).

Further, after the process shown in FIG. 3 (step S03), patterning into a contact shape by growth of a nitride film and lithography, dry etching of the nitride film, and removal of a resist film are carried out to form the first nitride film 7B, the first sidewall oxide film 8A, and the second nitride film 10A, followed by the process shown in FIG. 5 (step S05). Thereby, the number of processes can be reduced.

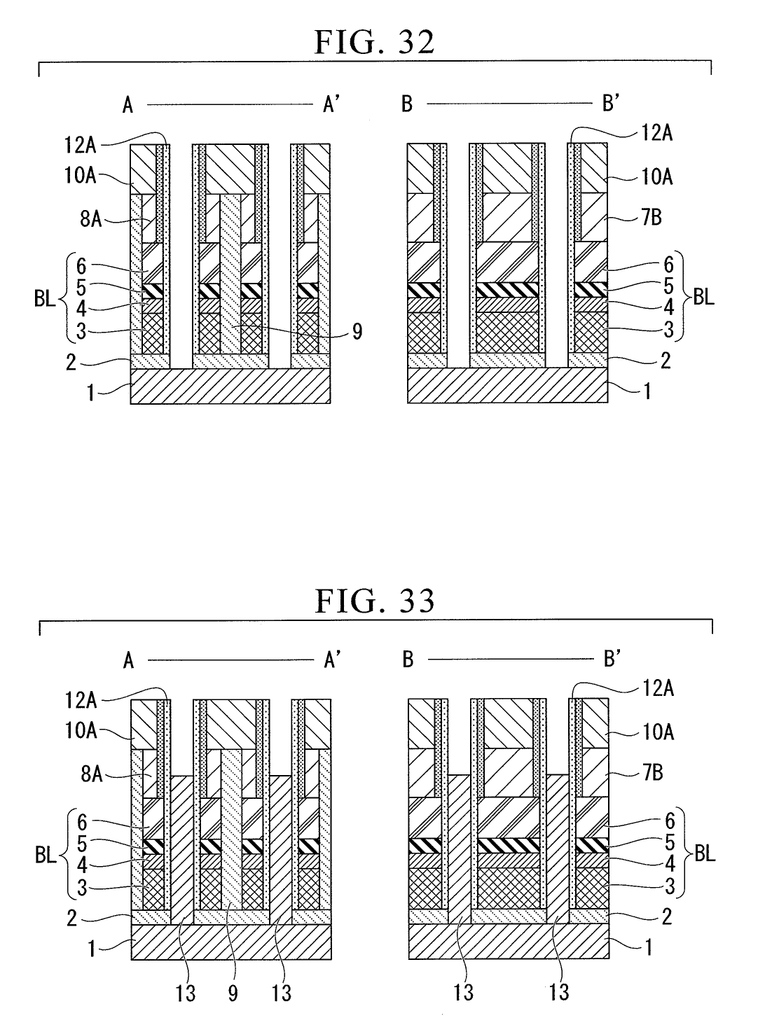

Moreover, the bit-line insulating film may be a nitride film, as shown in FIGS. 32 to 35.

After the structure shown in FIG. 5 (step S05) is complete, growth of a nitride film is carried out to form a nitride film 12A, followed by dry etching of the first oxide film 2. Thus, the structure shown in FIG. 32 is formed.

Then, selective epitaxial growth is carried out to form the first silicon layer 13. Then, hydrogen annealing may be carried out. Thus, the structure shown in FIG. 33 is formed.

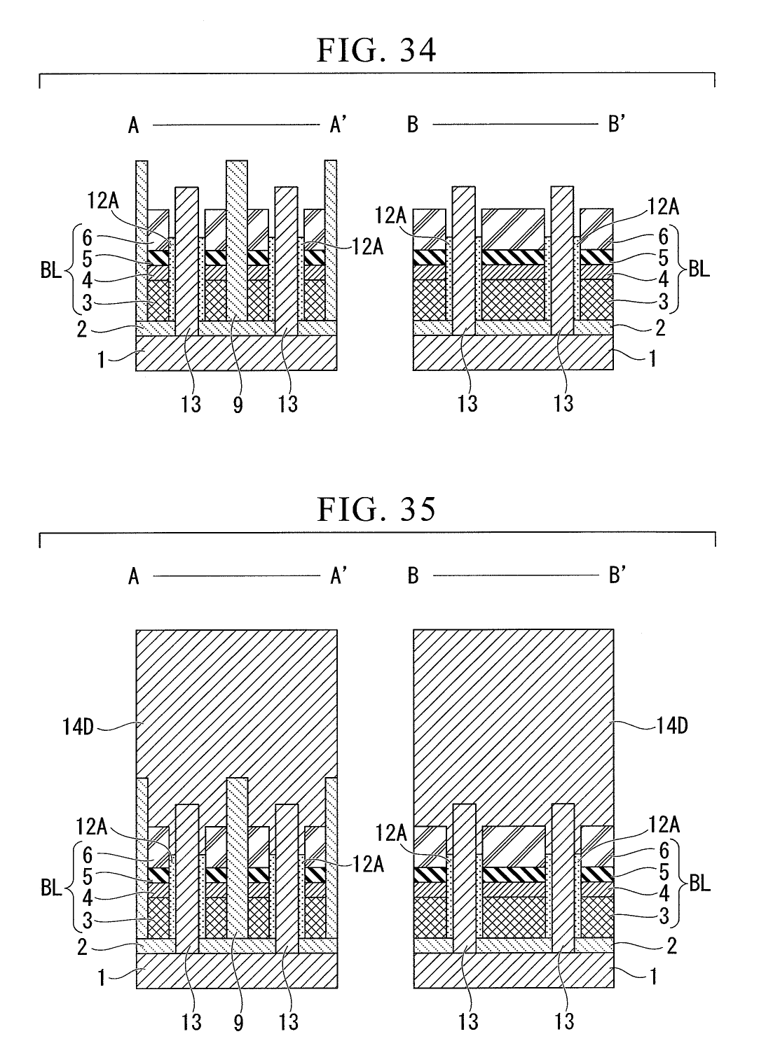

Then, the nitride film 12A is wet etched, thereby forming the structure shown in FIG. 34. Then, selective epitaxial growth is carried out to deposit a second silicon layer 14D over the entire surface.

Then, the device can be made by similar processes following the process shown in FIG. 10 (step S10). Since the nitride film 12A can be used as the sidewalls for the epitaxial growth, the selective epitaxial growth can be simplified.

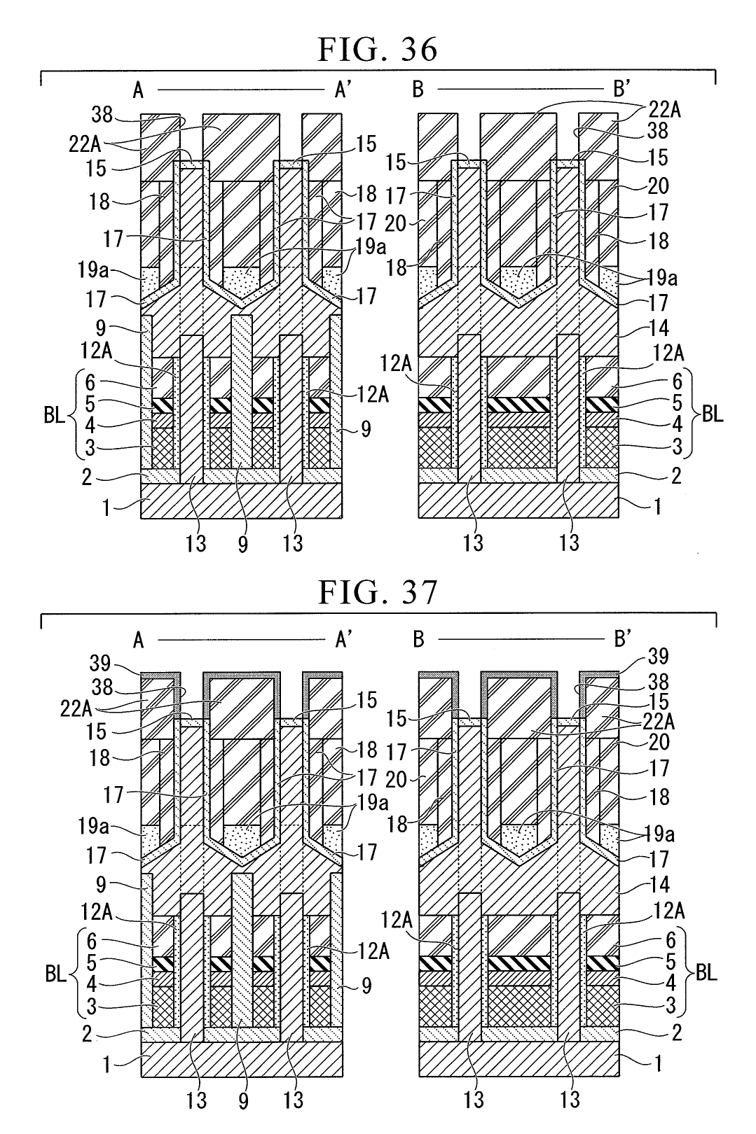

Alternatively, contacts may be formed above the transistor as shown in FIGS. 36 to 38.

After the structure shown in FIG. 12 (step S12) is complete, a fourth DOPOS layer 22A is formed, followed by wet etching the nitride film. Thereby, contact holes 38 are formed on the fourth oxide film 15 shown in FIG. 36. Then, the surface of the fourth DOPOS layer 24A is thermally oxidized to form an oxide film 39, as shown in FIG. 37.

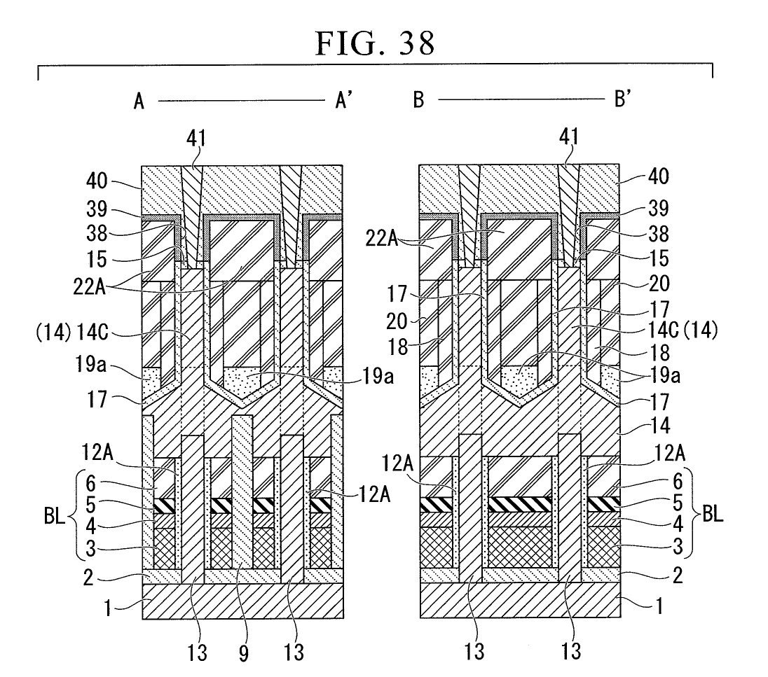

Then, an insulating film 40 is deposited over the contact holes 38 and the oxide film 39. Then, contacts 41 are formed by a known method, thus forming the structure shown in FIG. 38. Although an epitaxial growth apparatus is expensive, costs of manufacturing a semiconductor device can be reduced by use of the contacts 41.

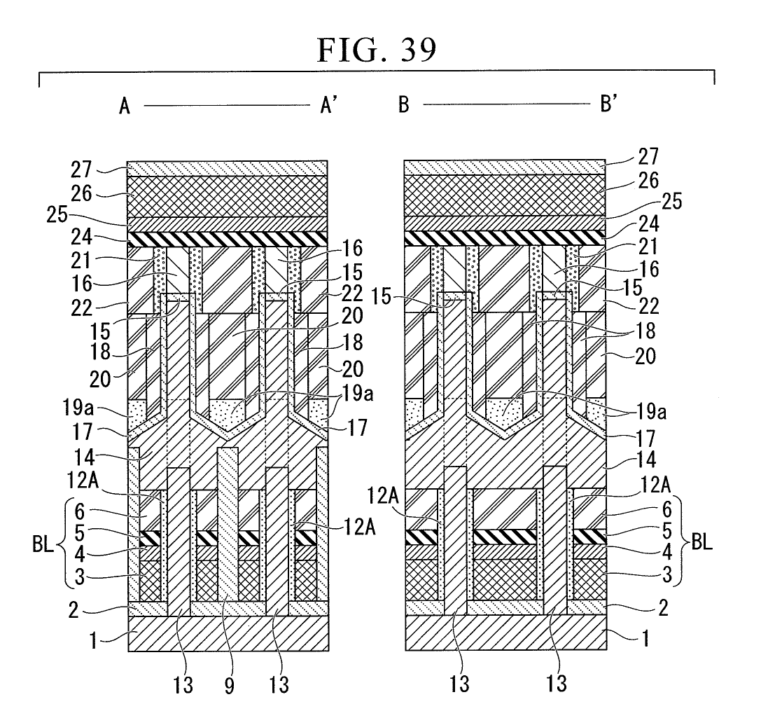

Additionally, after the structure shown in FIG. 14 (step S14) is complete, the fourth DOPOS layer 22 is formed to cover the second and third DOPOS layers 18 and 20, as shown in FIG. 39. Then, the height of the fourth DOPOS layer 22 is adjusted to that of the third nitride film 16 by CMP. Then, a second WSi layer 24, a second WN layer 25, a second W layer 26, and a sixth oxide film 27 are sequentially deposited to cover the fourth DPOS layer 22 and the third nitride film 16. Then, the device can be made by the similar processes following the process shown in FIG. 16 (step S16), thus reducing the number of processes (formation of the fifth DOPOS layer 23 can be omitted).

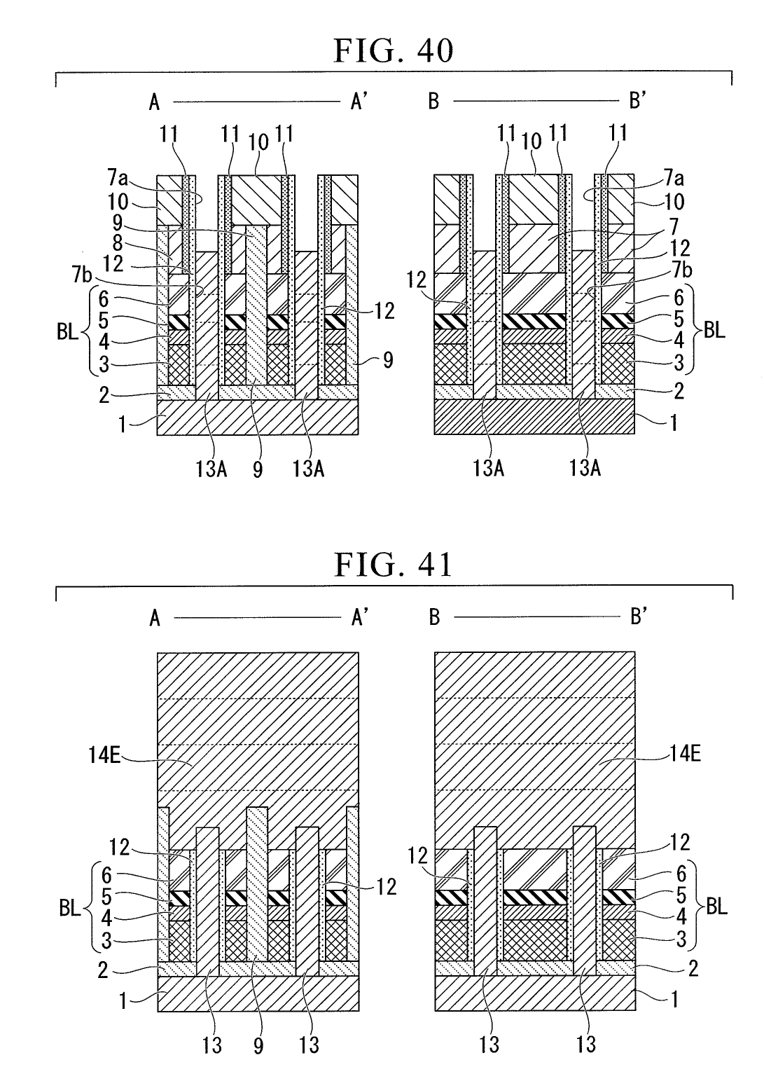

Further, after the structure shown in FIG. 6 (step S06) is complete, selective epitaxial growth and hydrogen annealing may be repeated in this order multiple times to form the first silicon layer 13A, as shown in FIG. 40. Then, the device can be formed by the similar processes following the process shown in FIG. 8 (step S08), thus reducing the number of crystal defects included in the first silicon layer 13A.

Moreover, after the structure shown in FIG. 8 (step S08) is complete, selective epitaxial growth and hydrogen annealing are repeated in this order multiple times to form a second silicon layer 14E, as shown in FIG. 41. Then, the device can be formed by the similar processes following the process shown in FIG. 10 (step S10), thus reducing the number of crystal defects included in the second silicon layer 14E.

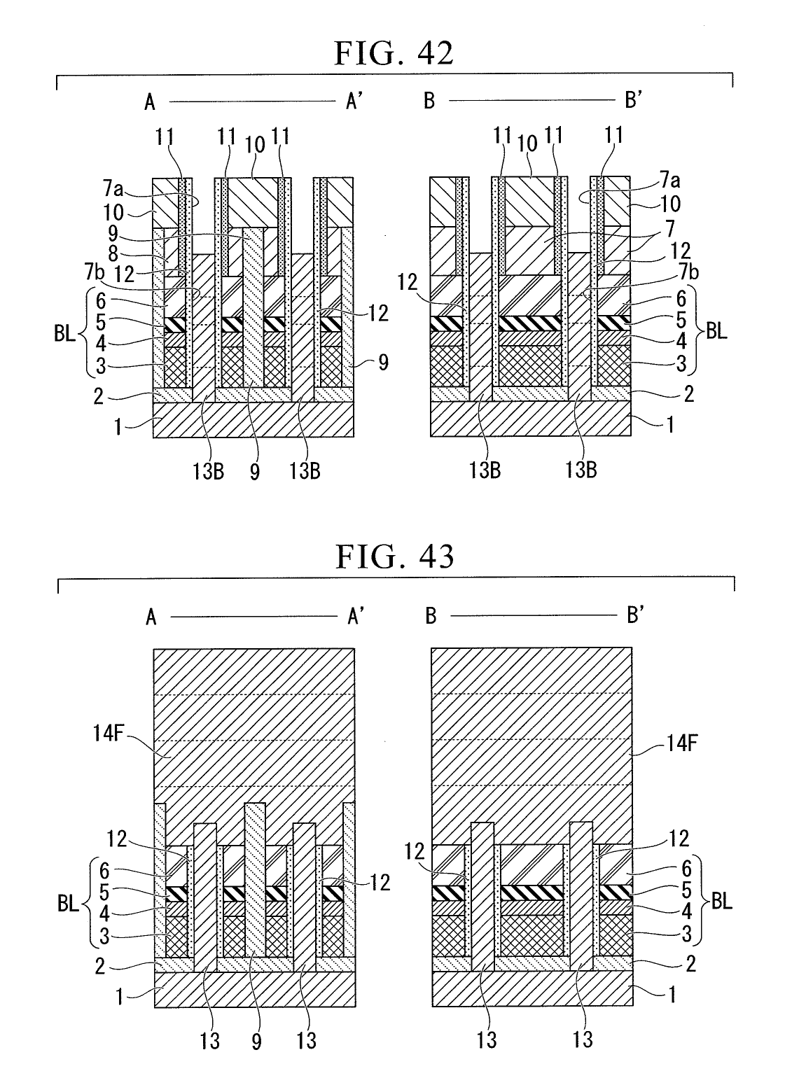

Alternatively, after the structure shown in FIG. 6 (step S06) is complete, selective epitaxial growth and hydrogen annealing are repeated in this order multiple times to form a first silicon layer 13B, as shown in FIG. 42. Then, the device can be formed by the similar processes following the process shown in FIG. 8 (step S08), thus reducing the number of crystal defects included in the first silicon layer 13B.

Additionally, after the structure shown in FIG. 8 (step S08) is complete, selective epitaxial growth and hydrogen annealing are repeated in this order multiple times to form a second silicon layer 14F, as shown in FIG. 43. Then, the device can be formed by the similar processes following the process shown in FIG. 10 (step S10), thus reducing the number of crystal defects included in the second silicon layer 14E.

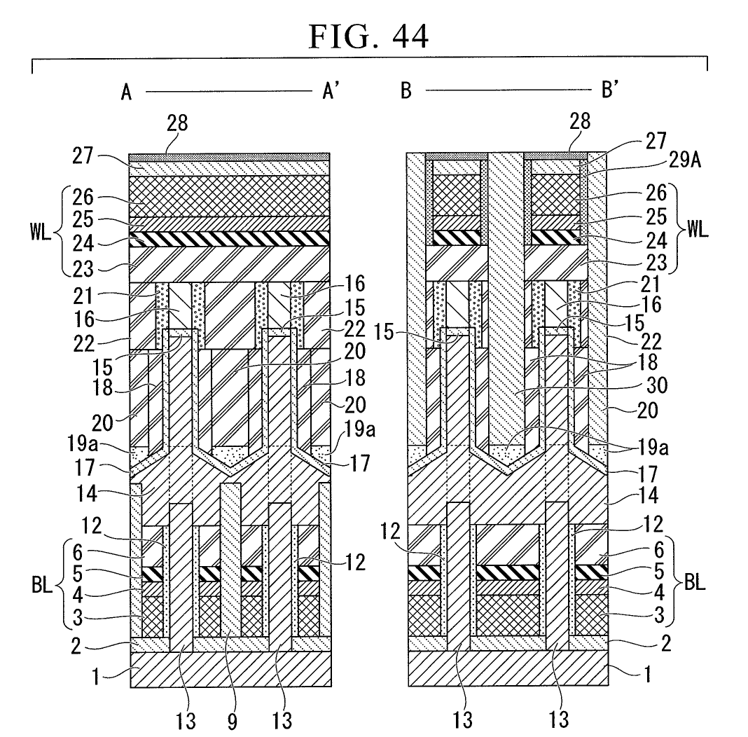

Further, after the structure shown in FIG. 15 (step S15) is complete, the sidewalls of the word lines WL can be partially replaced with a nitride film 29A, as shown in FIG. 44. In other words, after the structure shown in FIG. 15 (step S15) is complete, the sixth oxide film 27 is dry etched and patterned by lithography, followed by patterning the fifth DOPOS layer 23, the second WSi layer 24, the second WN layer 25, the second W layer 26, and the sixth oxide film 27 in a line-and-space pattern with the sixth oxide film 27 as a mask. At this time, the fifth DOPOS layer 23 and the like are patterned so as to extend in the direction perpendicular to the longitudinal direction of the first nitride film 7. Then, the nitride film 29A is formed to cover the fifth DOPOS layer 23, the second WSi layer 24, the second WN layer 25, the second W layer 26, and the sixth oxide film 27. Then, the third and fourth DOPOS layer 20 and 22 are dry etched, thus forming a recess 30a. Then, an eighth oxide film 30 is formed to fill the recess 30a, thus forming the structure shown in FIG. 44.

Then, the device can be formed by the similar processes following the process shown in FIG. 17 (step S17). Since the sidewalls of the word lines WL are the nitride film 29A, the W atom hardly escapes to the substrate, thereby enhancing the refresh characteristics of a device, such as DRAM or ZRAM, for which the refresh characteristics are important.

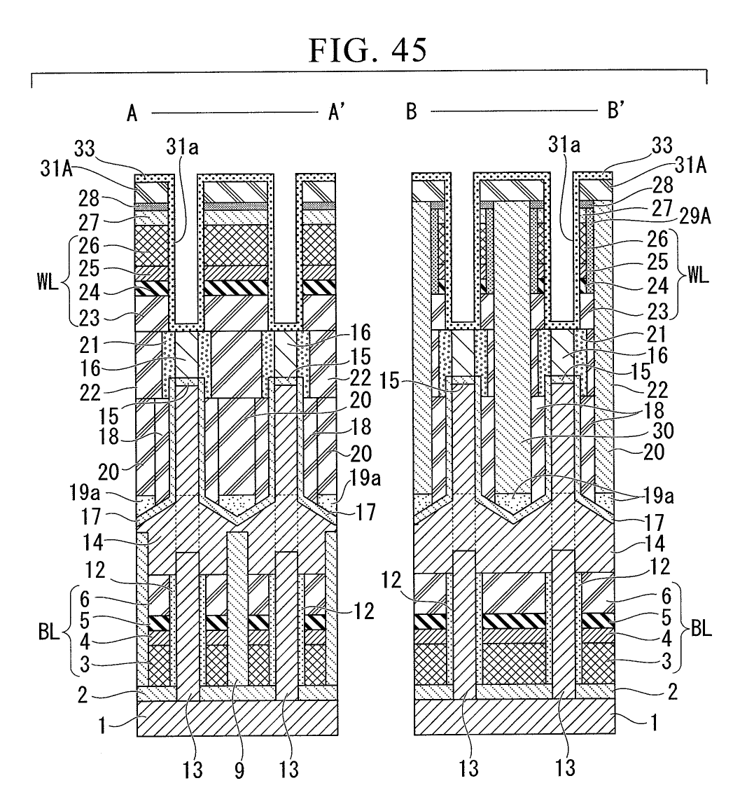

Moreover, the number of processes can be reduced after the structure shown in FIG. 16 (step S16) is complete, as shown in FIG. 45.

After the structure shown in FIG. 16 (step S16) is complete, CMP of an oxide film is carried out, followed by formation of a nitride film 31A, lithography to pattern the nitride film 31A in a contact shape, dry etching of the nitride film 31A, and then removal of a resist film. Then, the sixth oxide film 27, the second W layer 26, the second WSi layer 24, and the fifth DOPOS layer 23 are dry etched, followed by growth of an oxide film to form a ninth oxide film. Thus, the structure shown in FIG. 45 is formed.

Then, the device can be formed by the similar processes following the process shown in FIG. 18 (step S18). Thus, the number of processes can be reduced since formation of the second sidewall nitride film 32 can be omitted.

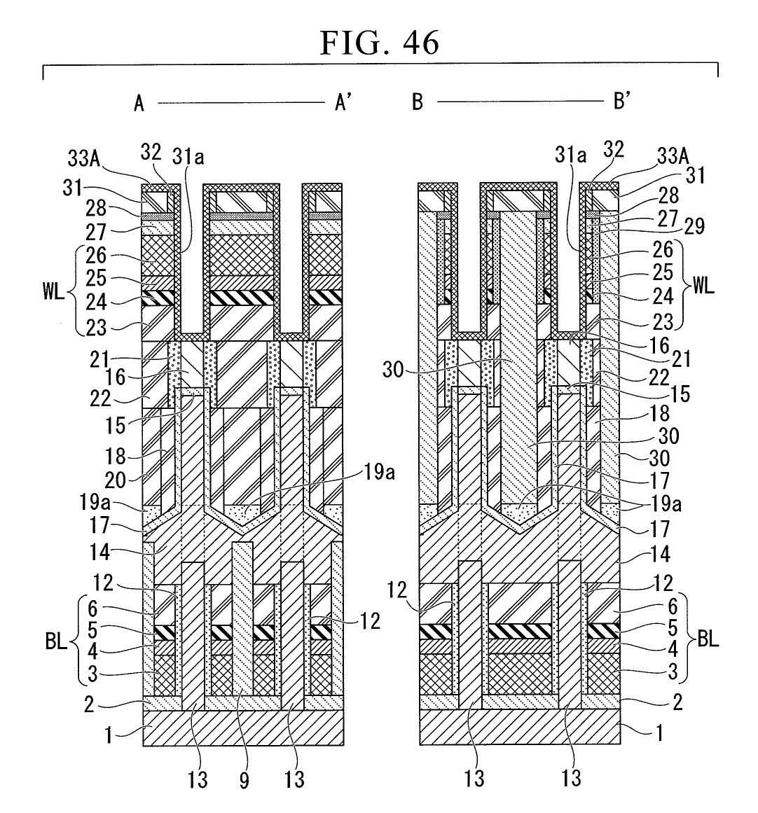

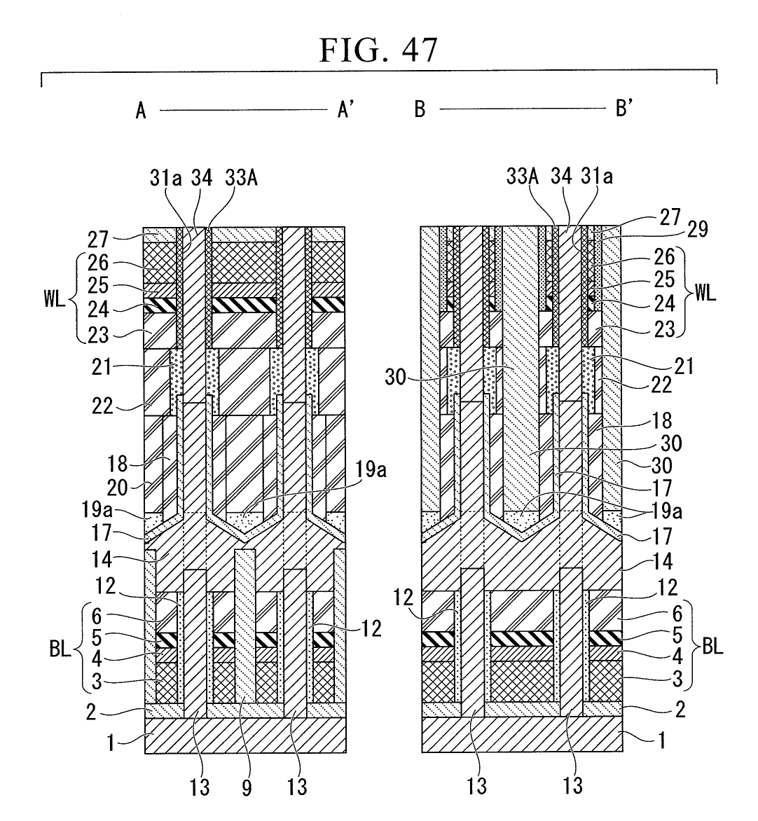

Alternatively, the sidewalls of the word lines WL can partially be a nitride film 33A after the structure shown in FIG. 16 (step S16) is complete, as shown in FIGS. 46 and 47.

After the structure shown in FIG. 16 (step S16) is complete, CMP of an oxide film is carried out, followed by growth of a nitride film to form a fourth nitride film 31. Then, the fourth nitride film 31 is patterned in a contact shape by lithography, followed by dry etching of the fourth nitride film 31 and removal of a resist film. Then, growth of the nitride film is carried out, followed by etch back of the nitride film to form a second sidewall nitride film 32. Further, the sixth oxide film 27, the second W layer 26, the second WN layer 25, the second WSi layer 24, and the fifth DOPOS layer 23 are dry etched. Then, a nitride film 33A is formed, thus forming the structure shown in FIG. 46.

Then, the bottom portions of the nitride film 33A and the third nitride film 16 are dry etched. At the same time, the upper portions of the nitride film 33A, the fourth nitride film 31, and the second sidewall nitride film 32 are removed. Then, the fourth oxide film 15 is dry etched, followed by selective epitaxial growth to form the third silicon layer 34, thus forming the structure shown in FIG. 47.

Then, the device can be formed by the similar processes following the process shown in FIG. 19 (step S19). Since the sidewalls of the word lines WL are the nitride film 33A, the W atom hardly escapes to the substrate, thereby enhancing the refresh characteristics of a device, such as DRAM or ZRAM, for which the refresh characteristics are important.

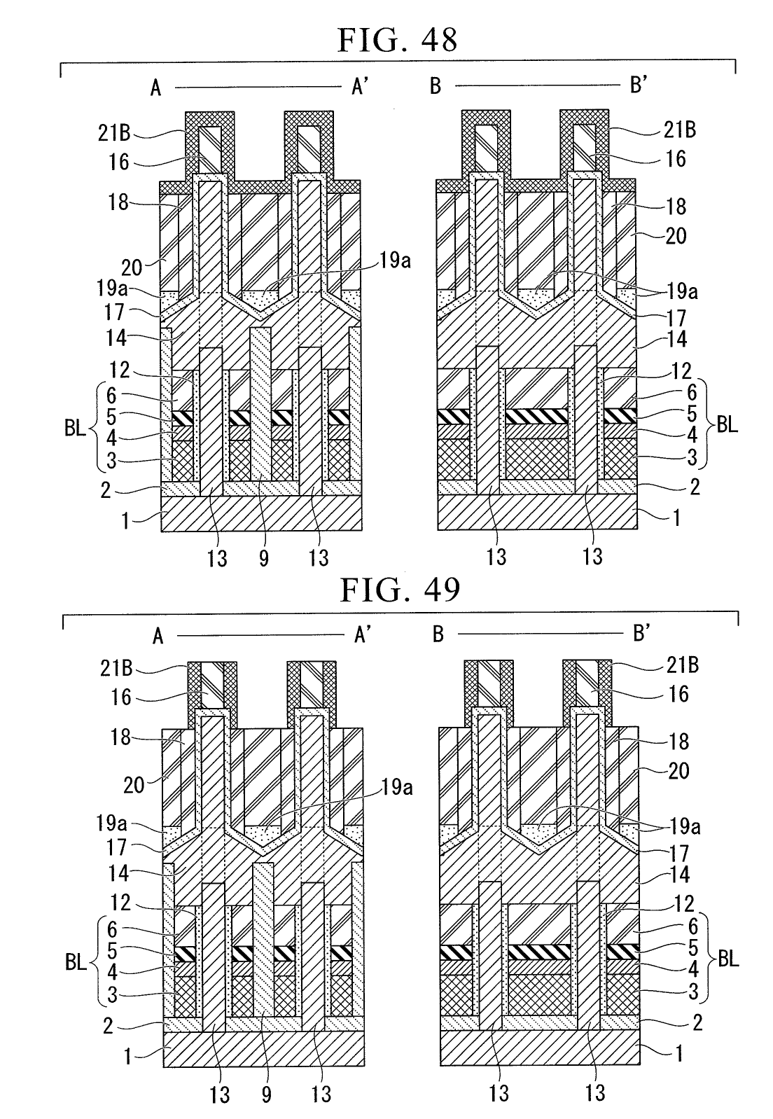

Additionally, a nitride film 21B can be formed on the upper sidewalls of the transistor, as shown in FIGS. 48 to 50.

After the structure shown in FIG. 12 (step S12) is complete, the second and third DOPOS layer 18 and 20 are dry etched. Then, the nitride film 21B is deposited over the entire surface, thus forming the structure shown in FIG. 48.

Then, the nitride film 21B is dry etched to remove the bottom and upper portions of the nitride film 21B, thus forming the structure shown in FIG. 49.

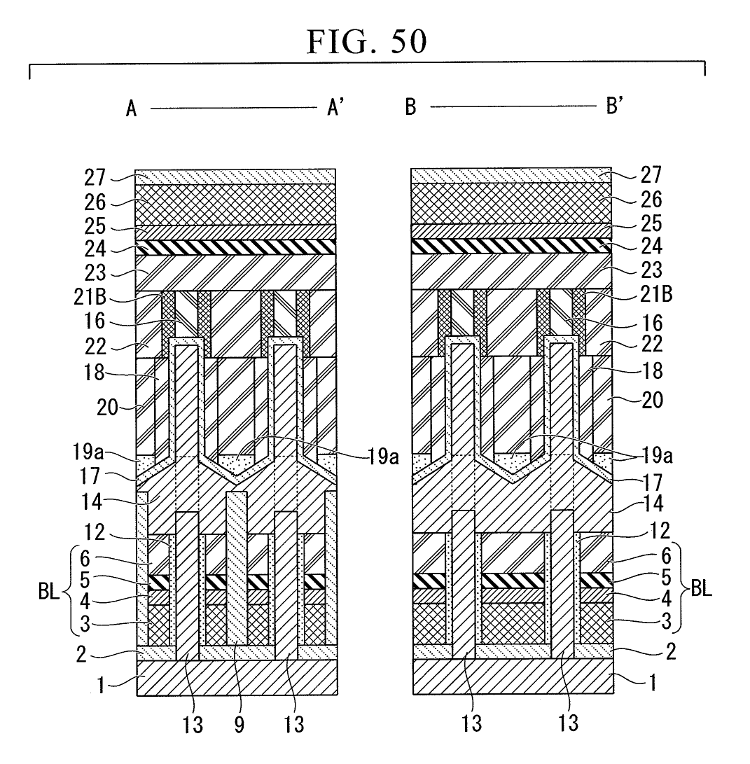

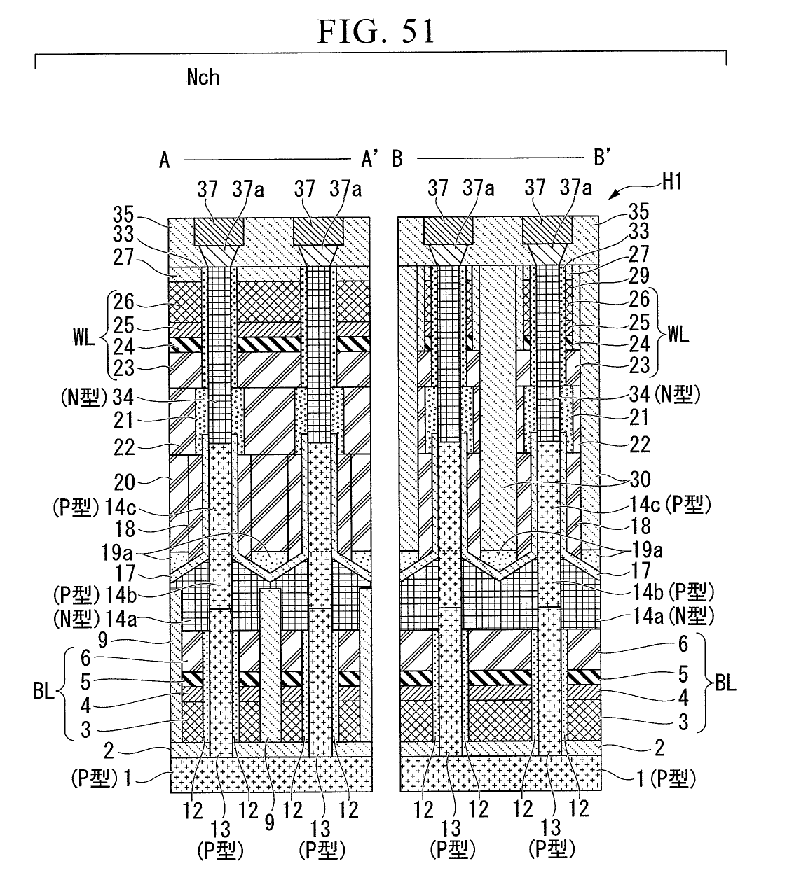

Then, a fourth DOPOS layer 22 is formed by growth, followed by CMP of the DOPOS layer. Then, the fifth DOPOS layer 23, the second WSi layer 24, the second WN layer 25, the second W layer 26, and the sixth oxide film 27 are formed, thus forming the structure shown in FIG. 50.

Then, the device can be formed by the similar processes following the process shown in FIG. 16 (step S16). By the nitride film 21B being formed on the upper sidewalls of the transistor, the nitride film 21B is used as sidewalls for the selective epitaxial growth, thereby simplifying the selective epitaxial growth.

As explained above, according to the method of manufacturing the semiconductor device of the present invention, bit and word lines are made of poly-metal or polycide, a semiconductor device including low-resistance bit and word lines can be formed. In case of forming the word line by only polysilicon layer, a semiconductor device having high density can easily be made. In case of forming the bit line by only polysilicon layer, a semiconductor device having small leak current characteristic can easily be made.

The present invention is applicable to a semiconductor device including vertical MOS transistors and a method of manufacturing the same.

It is apparent that the present invention is not limited to the above embodiments, but may be modified and changed without departing from the scope and spirit of the invention.

What is claimed is:

1. A method of manufacturing a semiconductor device, comprising:
forming a plurality of bit lines comprising at least one of a first silicide layer and a first polysilicon layer;
forming a plurality of through holes in the bit lines;
forming a first silicon layer to fill the through holes;
forming a second silicon layer over the bit lines and the first silicon layer, the second silicon layer comprising a base and a plurality of bodies standing on the base;
forming a gate insulating film and a gate electrode to cover the bodies;
forming a plurality of first source-and-drain regions under the respective bodies in the base;
forming a plurality of word lines connected to the gate electrode, the word lines comprising at least one of a second silicide layer and a second polysilicon layer; and
forming a plurality of second source-and-drain regions penetrating the word lines and connected to the respective bodies.

2. The method according to claim 1, further comprising:
forming a first nitride film on the bit lines after the bit lines are formed and before the through holes are formed;
etching the first nitride film in a line-and-space pattern; and
forming a first sidewall oxide film to cover every sidewall of the first nitride film patterned.

3. The method according to claim 1, further comprising
forming a third nitride film on the second silicon layer after the first source-and-drain regions are formed, and
forming a fifth oxide film to cover the third nitride film.

4. The method according to claim 1, wherein
the second silicon layer is formed by epitaxial growth, and
the base and the bodies are formed by etching the second silicon layer.

5. The method according to claim 4, wherein the epitaxial growth is carried out with an upper portion of the first silicon layer which is made to protrude from the bit lines as a seed.

6. The method according to claim 1, wherein the second silicon layer is formed by epitaxial growth and annealing.

7. The method according to claim 1, wherein the annealing is any one of laser annealing and hydrogen annealing.

8. The method according to claim 1, further comprising
forming a high-density plasma oxide film to cover the base and the bodies so as to be thinner only on sidewalls of the bodies than on other portions, and
forming gate stoppers between the bodies on the base by isotropically etching the high-density plasma oxide film.

9. The method according to claim 4, wherein the base and the bodies are formed such that boundaries between the base and the bodies have a taper shape.

10. The method according to claim 1, wherein at least one of the first silicide layer and the second silicide layer includes a refractory metal layer.

11. The method according to claim 10, wherein the refractory metal comprises a tungsten layer or a tungsten nitride layer.

12. The method according to claim 1, wherein at least one of the first silicide layer and the second silicide layer comprises any one of tungsten silicide, cobalt silicide, nickel silicide, titanium silicide, molybdenum silicide, and chromium silicide.

13. The method according to claim 1, wherein
the bit lines are poly-metal wirings including the first silicide layer and the first polysilicon layer, and
the word lines are poly-metal wirings including the second silicide layer and the second polysilicon layer.

14. The method according to claim 1, wherein at least one of the bit line and the word line is a polysilicon wiring which does not include the first and the second silicide layers.

15. The method according to claim 1, wherein both the bit line and the word line are polysilicon wirings which do not include the first and the second silicide layers.

16. A semiconductor device, comprising:
a plurality of first silicon pillars disposed on a surface of a semiconductor substrate;
a bit line extending in a first direction, and surrounding each of the first silicon pillar with an intervention of a first insulating film between a side surface of the first silicon pillar and said bit line;
a plurality of second silicon pillars disposed on each upper surface of the first silicon pillars;
a word line extending in a second direction which is perpendicular to the first direction, and surrounding each of the second silicon pillar with an intervention of a second insulating film between a side surface of the second silicon pillar and said word line;
a first diffusion layer disposed at a base portion of each second silicon pillar, connecting to the bit line, and functioning as one of source and drain regions of a transistor; and
a second diffusion layer disposed at an upper portion of each second silicon pillar, and functioning as the other of the source and drain regions.

17. The semiconductor device according to claim 16, wherein at least one of the bit line and the word line includes a refractory metal layer.

18. The semiconductor device according to claim 16, wherein the first silicon pillar has a first conductivity type and the second silicon pillar has a second conductivity type which is contrary to the first conductivity type.

19. The semiconductor device according to claim 16, wherein the base portion of the second silicon pillar has a taper shape.

20. The semiconductor device according to claim 16, wherein a level of an upper surface of the word line is higher than a level of an upper surface of the second silicon pillar.
